(19) United States
(12) Patent Application Publication
(10) Pub. No.: US 2012/0135357 A1
(43) Pub. Date: May 31, 2012

(54) POLYMER, POSITIVE RESIST COMPOSITION, AND PATTERNING PROCESS

(76) Inventors: Tomohiro KOBAYASHI, Joetsu-shi (JP); Takayuki Nagasawa, Joetsu-shi (JP); Ryosuke Taniguchi, Joetsu-shi (JP); Youichi Ohsawa, Joetsu-shi (JP); Kenji Funatsu, Joetsu-shi (JP); Seiichiro Tachibana, Joetsu-shi (JP)

(21) Appl. No.: 13/303,283

(22) Filed: Nov. 23, 2011

(30) Foreign Application Priority Data
Nov. 25, 2010 (JP) 2010-262372

(51) Int. Cl. G03F 7/20; C08F 214/18

(52) U.S. Cl. 430/326; 526/243

(57) ABSTRACT

A positive resist composition comprising a polymer comprising recurring units of a specific structure adapted to generate an acid upon exposure to high-energy radiation, recurring units of a lactone ring-containing structure, and acid labile units, all the recurring units being free of hydroxyl, can form a fine size pattern having a rectangular profile and improved collapse resistance.

### CROSS-REFERENCE TO RELATED APPLICATION

This non-provisional application claims priority under 35 U.S.C. §119(a) on Patent Application No. 2010-262372 filed in Japan on Nov. 25, 2010, the entire contents of which are hereby incorporated by reference.

### TECHNICAL FIELD

This invention relates to a polymer, a positive resist composition comprising the polymer as a base resin, and a pattern forming process using the composition. The positive resist composition lends itself to lithography using ArF excimer laser with wavelength 193 nm for micropatterning in the fabrication of semiconductor devices, especially immersion lithography where water is interposed between a projection lens and a wafer.

### BACKGROUND ART

In the recent drive for higher integration densities and operating speeds in LSI devices, the pattern rule is made drastically finer. The photolithography which is currently on widespread use in the art is approaching the essential limit of resolution determined by the wavelength of a light source.

As the light source used in the lithography for resist pattern formation, g-line (436 nm) or i-line (365 nm) from a mercury lamp was widely used in the past. Reducing the wavelength of exposure light was believed effective as the means for further reducing the feature size. For the mass production process of 64 MB dynamic random access memories (DRAM, processing feature size 0.25 μm or less) and later ones, the exposure light source of i-line (365 nm) was replaced by a KrF excimer laser having a shorter wavelength of 248 nm.

However, for the fabrication of DRAM with a degree of integration of 256 MB and 1 GB or more requiring a finer patterning technology (processing feature size 0.2 μm or less), a shorter wavelength light source was required. Photolithography using ArF excimer laser light (193 nm) has been under active investigation.

It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices.

For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the F₂ lithography was postponed and instead, the early introduction of ArF immersion lithography was advocated (see Proc. SPIE Vol. 4690 xxix).

In the ArF immersion lithography, water is held between the projection lens and the wafer. Since water has a refractive index of 1.44 at 193 nm, pattern formation is possible even using a lens with NA of 1.0 or greater. Theoretically the NA of lens can be increased to 1.35. The resolution is improved by an increment of NA. A combination of a lens having NA of at least 1.2 with strong super-resolution technology suggests a way to the 45-nm node (see Proc. SPIE Vol. 5040, p 724, 2003).

However, as the circuit line width is reduced, the influence of contrast being degraded by acid diffusion becomes more serious for the resist material. The reason is that the pattern feature size is approaching the diffusion length of acid, and this causes a lowering of mask fidelity and a degradation of pattern rectangularity. Accordingly, to gain more benefits from a reduction of exposure light wavelength and an increase of lens NA, the resist material is required to increase a dissolution contrast or restrain acid diffusion, as compared with the prior art materials.

Another problem which becomes more serious as the pattern feature size is reduced is pattern collapse. The pattern is more likely to collapse, not only due to the influence of degraded contrast, but also because the critical dimension is reduced so that the area of contact with the substrate becomes narrower.

For restraining acid diffusion, an attempt was made to bind a photoacid generator in a base polymer. Among others, the polymer which is designed such that an acid generated upon light exposure is bound in its structure is advantageous in that acid diffusion is substantially restrained and exposure dose dependency and mask fidelity are improved (see JP-A 2008-133448).

This design is still insufficient with respect to pattern collapse. It is necessary to improve the contrast of latent image by restraining acid diffusion and to control the dissolution behavior during development.

The behavior during the development step that affects pattern collapse is a swell phenomenon. This phenomenon is accounted for by a random distribution of hydrophobic and hydrophilic portions on a pattern sidewall. The developer penetrates into the hydrophilic portions, but the hydrophobic portions are not dissolved, and consequently the pattern is swollen. Because of stresses thus generated, the pattern collapses. Particularly ArF resist materials often use carboxylic acid (carboxylic acid protected with an acid labile group in the case of positive resist material) as the alkali-soluble group in the base polymer and tend to undergo a noticeable swell as compared with KrF resist materials based on weaker acidity polyhydroxystyrene (PHS).

As the means for avoiding swell, an investigation was made to introduce a phenol structure into the base polymer in the ArF resist material. It was proposed to introduce naphthol units which are relatively transparent to ArF radiation of wavelength 193 nm (see Jpn. J. Appl. Phys. Vol. 33 (12B), p. 7028 (1994)). This proposal failed to provide a high transparency necessary to prevent a fine pattern from being tapered.

Also an alkali-soluble group having an acidity approximate to phenol units was proposed. Specifically, a resin possessing an alcohol having a plurality of fluorine atoms substituted at α- and α′-positions (e.g., having a partial structure: —C(CF₃)₂OH) as the alkali-soluble functional group was proposed (G. Wallraff et al., “Active Fluororesists for 157 nm Lithography,” 2nd International Symposium on 157 nm Lithography, May 14-17, 2001). This proposal is effective in solving the swell problem to some extent without detracting from transparency to ArF radiation.

When acidic units are introduced into a base polymer in a positive resist material, however, they may function to increase the alkali dissolution rate of unexposed portions and reduce the dissolution contrast. This may invite a shortage of resolution and lead to a top-loss profile.

In many examples proposed thus far, non-acidic hydroxyl-containing units as typified by 3-hydroxy-1-adamantyl (meth)acrylate are introduced. These units are effective for improving exposure dose dependency due to their acid diffusion restraining effect and also avoid a drop of dissolution contrast unlike acidic hydroxyl groups. Due to the high hydrophilicity of hydroxyl groups, these units facilitate penetration of developer or rinse water, but not dissolution. Therefore, these units are ineffective for mitigating swell and may sometimes serve to increase swell.

### CITATION LIST

Patent Document 1: JP-A 2008-133448 (U.S. Pat. No. 7,569,326)
Non-Patent Document 1: Proc. SPIE Vol. 4690 xxix
Non-Patent Document 2: Proc. SPIE Vol. 5040 p. 724
Non-Patent Document 3: Jpn. J. Appl. Phys. Vol. 33 (12B), p. 7028 (1994)
Non-Patent Document 4: G. Wallraff et al., “Active Fluororesists for 157 nm Lithography,” 2nd International Symposium on 157 nm Lithography, May 14-17, 2001

### DISCLOSURE OF INVENTION

An object of the invention is to provide a polymer is capable of meeting both the requirements of restrained acid diffusion and high dissolution contrast, forming a fine size pattern of rectangular profile, and improving resistance to pattern collapse; a positive resist composition comprising the polymer as a base resin; and a pattern forming process using the composition.

The inventors have found that a positive resist composition comprising a polymer comprising recurring units of a specific structure adapted to generate an acid upon exposure to high-energy radiation, recurring units of a specific lactone ring-containing structure, and acid labile units, the foregoing recurring units being free of hydroxyl, can form a fine size pattern having a more rectangular profile and improved collapse resistance.

It is believed that the exclusion of acidic hydroxyl groups prevents a pattern top loss, and the exclusion of non-acidic hydroxyl groups which tend to invite swell is in favor of pattern collapse resistance, whereas the swell inhibition and acid diffusion reduction effects which are otherwise exerted by hydroxyl-containing units must be compensated for by another means. By copolymerizing specific lactone ring-containing units with PAG-bound units, a copolymer can be formed which is endowed with an appropriate hydrophilic/hydrophobic balance, an appropriate generated acid strength, and low acid diffusion.

Briefly stated, the invention provides a polymer comprising recurring units of a specific structure adapted to generate an acid upon exposure to high-energy radiation, recurring units of a specific lactone ring-containing structure, and acid labile units, wherein all the recurring units are free of hydroxyl; a positive resist composition comprising the polymer; and a pattern forming process using the composition.

In one aspect, the invention provides a polymer comprising as an essential unit, at least one recurring unit of a structure adapted to generate an acid in response to high-energy radiation selected from UV, deep UV, electron beam, x-ray, excimer laser, γ-ray and synchrotron radiation, having the general formula (1a) and/or (1b).

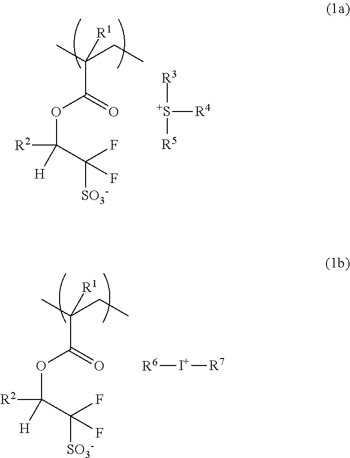

Herein R² is hydrogen or methyl, and R² is hydrogen or trifluoromethyl. In formula (1a), R³, R⁴, and R⁵ are each independently a substituted or unsubstituted, straight, branched or cyclic C₁-C₁₀ alkyl, alkenyl or oxoalkyl group, or substituted or unsubstituted C₆-C₁₈ aryl, aralkyl or aryloxoalkyl group, any two of R³, R⁴, and R⁵ may bond together to form a ring with the sulfur atom. In formula (1b), R⁶ and R⁷ are each independently a substituted or unsubstituted C₆-C₁₈ aryl group.

The polymer should also comprise as an essential unit, at least one recurring unit of a lactone ring-containing structure having the general formula (2a) and/or (2b).

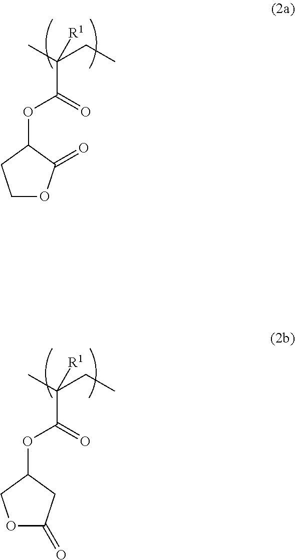

Herein R¹ is hydrogen or methyl.

The polymer should also comprise as an essential unit, at least one acid labile unit having the general formula (3).

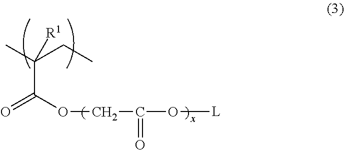

Herein R¹ is hydrogen or methyl, x is 0 or 1, and L is an acid labile group, which will be described later.

The foregoing recurring units should be free of hydroxyl.

In another aspect, the invention provides a positive resist composition comprising the polymer defined above as a base resin.

In a further aspect, the invention provides a pattern forming process comprising the steps of coating the positive resist composition defined above onto a substrate and heat treating to form a resist film, exposing the resist film to high-energy radiation, and developing with a developer.

The process may further include the step of post-exposure heat treatment prior to the development step, and various subsequent steps such as etching, resist removal, and cleaning.

In a preferred embodiment, the high-energy radiation has a wavelength in the range of 180 to 250 nm.

In a preferred embodiment, the exposing step is to expose the resist film to high-energy radiation via a liquid according to the immersion lithography. In a further preferred embodiment, a protective film is formed on the resist film, and in the exposing step of immersion lithography, a liquid is interposed between the protective film and a projection lens. Typically, the high-energy radiation has a wavelength in the range of 180 to 250 nm. Typically the liquid is water.

### ADVANTAGEOUS EFFECTS OF INVENTION

The polymer of the invention is useful as a base resin in a positive resist composition. The composition forms a fine size pattern of rectangular profile and offers improved resistance to pattern collapse.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group.

The acronym “PAG” stands for photoacid generator, and “PEB” for post-exposure bake.

The term “high-energy radiation” is intended to encompass ultraviolet (UV) radiation, deep UV, electron beam (EB), x-ray, excimer laser, γ-ray and synchrotron radiation.

One embodiment of the invention is a polymer comprising recurring units of a structure adapted to generate an acid in response to high-energy radiation selected from UV, deep UV, electron beam, x-ray, excimer laser, γ-ray and synchrotron radiation, having the general formula (1a) and/or (1b), recurring units of a lactone ring-containing structure having the general formula (2a) and/or (2b), and acid labile units having the general formula (3), all the recurring units being free of hydroxyl.

The recurring units of a structure adapted to generate an acid in response to high-energy radiation have the general formula (1a) and/or (1b).

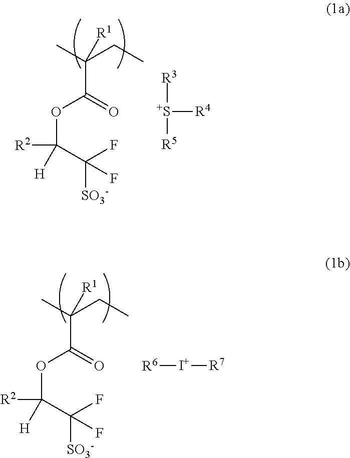

Herein R¹ is hydrogen or methyl, and R² is hydrogen or trifluoromethyl. In formula (1a), R³, R⁴, and R⁵ are each independently a substituted or unsubstituted, straight, branched or cyclic C₁-C₁₀ alkyl, alkenyl or oxoalkyl group, or a substituted or unsubstituted C₆-C₁₈ aryl, aralkyl or aryloxoalkyl group, any two of R³, R⁴, and R⁵ may bond together to form a ring with the sulfur atom. In formula (1b), R⁶ and R⁷ are each independently a substituted or unsubstituted C₆-C₁₈ aryl group.

Specifically, in formulae (1a) and (1b), R¹ is hydrogen or methyl, and R² is hydrogen or trifluoromethyl. In formula (1a), R³, R⁴, and R⁵ are each independently a substituted or unsubstituted, straight, branched or cyclic C₁-C₁₀ alkyl, alkenyl or oxoalkyl group, or substituted or unsubstituted C₆-C₁₈ aryl, aralkyl or aryloxoalkyl group.

Suitable alkyl groups include methyl, ethyl, n-propyl, isopropyl, n-butyl, tert-butyl, cyclopropyl, cyclopentyl, cyclohexyl, cyclopropylmethyl, 4-methylcyclohexyl, cyclohexylmethyl, norbornyl, and adamantyl. Suitable alkenyl groups include vinyl, allyl, propenyl, butenyl, hexenyl, and cyclohexenyl. Suitable oxoalkyl groups include 2-oxocyclopentyl, 2-oxocyclohexyl, 2-oxopropyl, 2-oxoethyl, 2-cyclopentyl-2-oxoethyl, 2-cyclohexyl-2-oxoethyl, and 2-(4-methylcyclohexyl)-2-oxoethyl. Suitable aryl groups include phenyl, naphthyl and thienyl, as well as hydroxyphenyl groups such as 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, and 3-tert-butoxyphenyl, alkylphenyl groups such as 2-methylphenyl, 3-methylphenyl, 4-methylphenyl, 4-ethylphenyl, 4-tert-butylphenyl, 4-n-butylphenyl, and 2,4-dimethylphenyl, alkylnaphthyl groups such as methylnaphthyl and ethylnaphthyl, alkoxynaphthyl groups such as methoxynaphthyl and ethoxynaphthyl, dialkylnaphthyl groups such as dimethylnaphthyl and diethylnaphthyl, and dialkoxynaphthyl groups such as dimethoxynaphthyl and diethoxynaphthyl. Suitable aralkyl groups include benzyl, 1-phenylethyl, and 2-phenylethyl. Suitable aryloxoalkyl groups include 2-aryl-2-oxoethyl groups such as 2-phenyl-2-oxoethyl, 2-(1-naphthyl)-2-oxoethyl, and 2-(2-naphthyl)-2-oxoethyl. In these groups, some hydrogen atoms may be substituted by fluorine atoms or hydroxyl groups. When any two of R³, R⁴, and R⁵ bond together to form a ring with the sulfur atom in the formula, suitable rings are shown below.

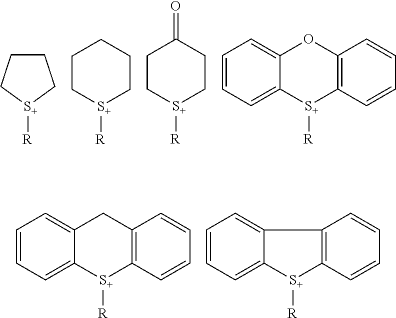

Herein R is as exemplified for R³, R⁴, and R⁵.

In formula (1b), R⁶ and R⁷ are each independently a substituted or unsubstituted C₆-C₁₈ aryl group. Exemplary aryl groups are the same as exemplified for R³, R⁴, and R⁵.

The recurring unit of formula (1a) or (1b) may be obtained by copolymerizing a monomer having the general formula (1a′) or (1b′) with another monomer.

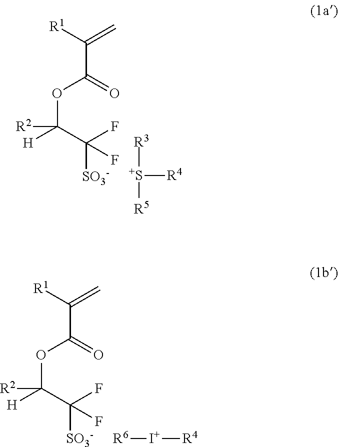

Herein R¹ to R⁷ are as defined above.

Examples of the unit having formula (1a) include compounds of the structure shown below, but are not limited thereto. From the standpoints of solubility in resist solvents and stability, it is preferred that R³ to R⁵ be phenyl and R² be trifluoromethyl.

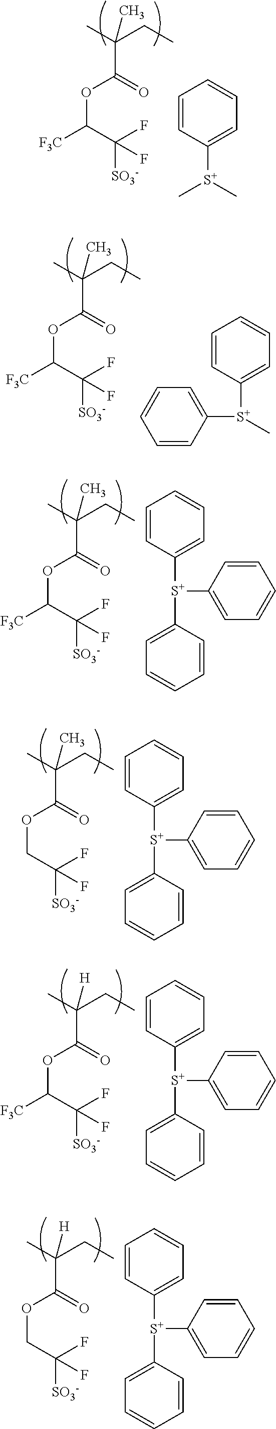

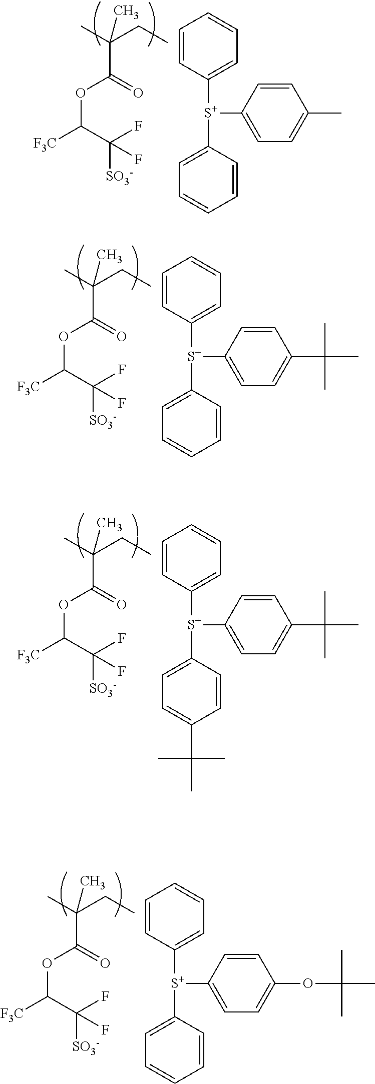

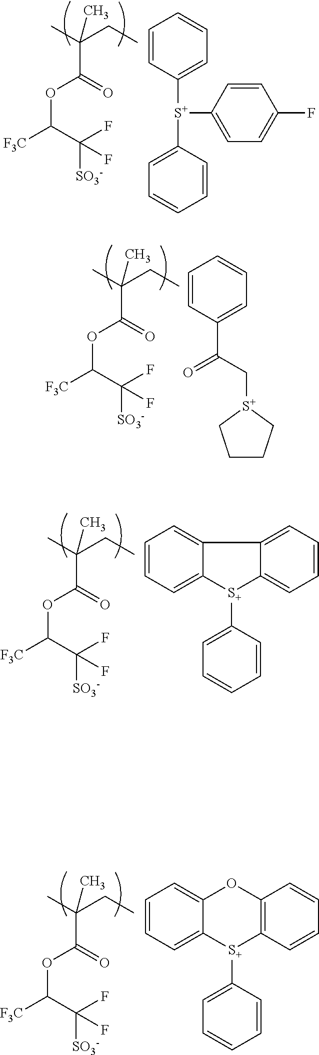

Examples of the unit having formula (1b) include compounds of the structure shown below, but are not limited thereto. From the standpoints of solubility in resist solvents and stability, it is preferred that R⁶ and R⁷ be 4-tert-butylphenyl and R² be trifluoromethyl.

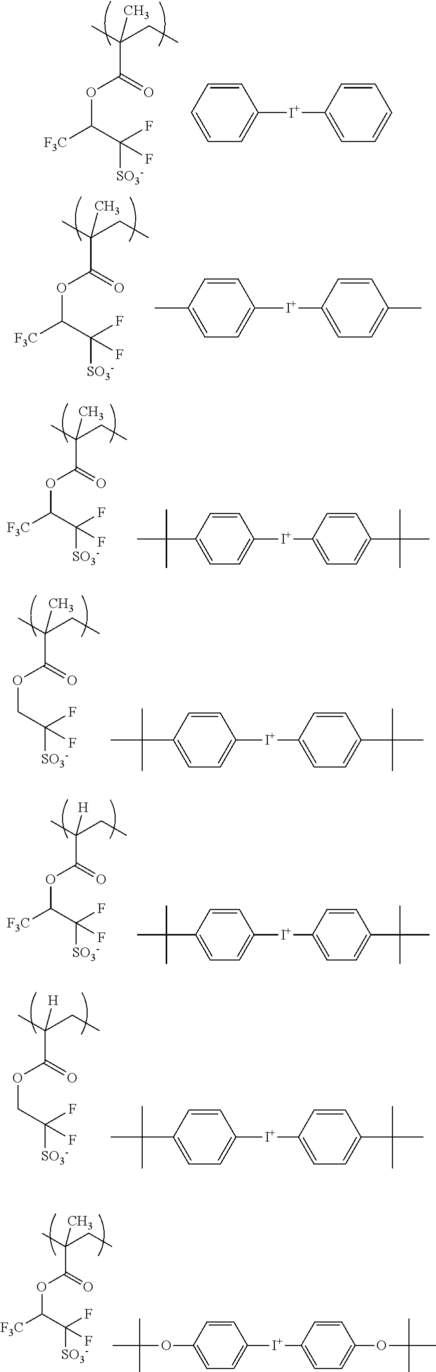

The polymer should also comprise as an essential unit, at least one recurring unit of a lactone ring-containing structure having the general formula (2a) and/or (2b).

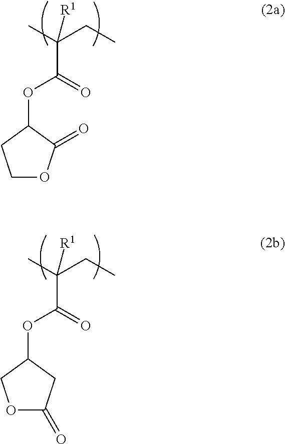

Herein R¹ is hydrogen or methyl.

The recurring unit of formula (2a) or (2b) may be obtained by copolymerizing a monomer having the general formula (2a′) or (2b′) with another monomer.

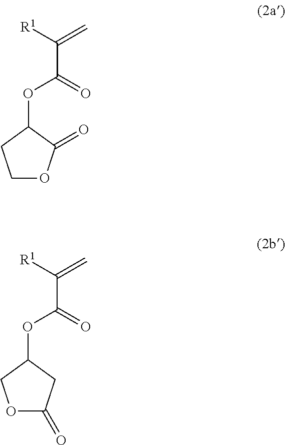

Herein R¹ is as defined above.

The polymer should further comprise as an essential unit, at least one acid labile unit having the general formula (3).

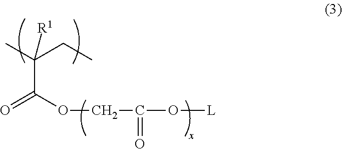

Herein R¹ is hydrogen or methyl, x is 0 or 1, and L is an acid labile group, which will be described just below.

The recurring unit of formula (3) may be obtained by copolymerizing a monomer having the general formula (3′) with another monomer.

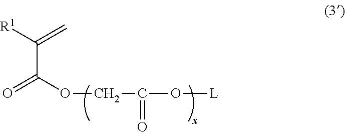

Herein R¹, x and L are as defined above.

The acid labile unit is a recurring unit of the structure containing a carboxylic acid, phenol or fluoroalcohol having an acidic group which is protected with an acid labile group. Deprotection occurs under the action of an acid whereby the unit serves to improve the solubility of the polymer in an alkaline developer. The recurring unit of formula (3) as one essential unit of the inventive polymer has the structure in which carboxylic acid is protected with an acid labile group L. The acid labile group L may be selected from a variety of such groups. Specifically, suitable acid labile groups L include alkoxymethyl groups of the following general formula (L1) and tertiary alkyl groups of the following general formulae (L2) to (L8), but are not limited thereto. More preferred acid labile groups are those of formulae (L2) to (L5).

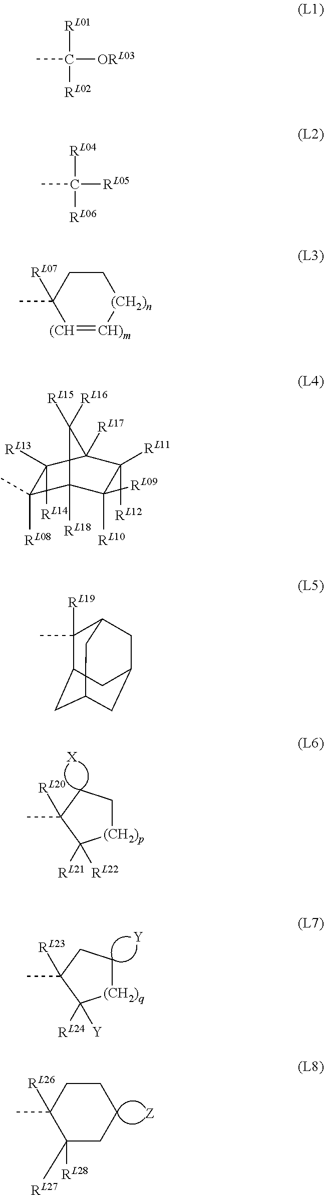

Herein and throughout the specification, the broken line denotes a valence bond.

In formula (L1), R^{L01} and R^{L02} are hydrogen or straight, branched or cyclic alkyl groups of 1 to 18 carbon atoms, preferably 1 to 10 carbon atoms, examples of which include methyl, ethyl, propyl, isopropyl, n-butyl, sec-butyl, tert-butyl, cyclopentyl, cyclohexyl, 2-ethylhexyl, n-octyl, and adamantyl. R^{L03} is a monovalent hydrocarbon group of 1 to 18 carbon atoms, preferably 1 to 10 carbon atoms, which may contain a heteroatom such as oxygen, examples of which include straight, branched or cyclic alkyl groups and substituted forms of these groups in which some hydrogen atoms are replaced by hydroxyl, alkoxy, oxo, amino, alkylamino or the like. Suitable straight, branched or cyclic alkyl groups are as exemplified for R^{L01} and R^{L02}. Exemplary substituted alkyl groups are illustrated below.

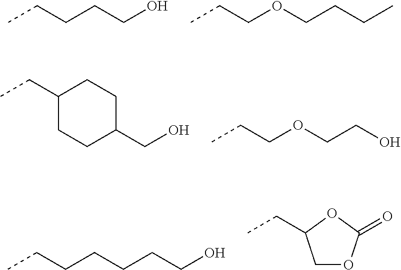

A pair of R^{L01} and R^{L02}, R^{L01} and R^{L03}, or R^{L02} and R^{L03} may bond together to form a ring with the carbon and oxygen atoms to which they are attached. Each of R^{L01} and R^{L02}, R^{L01} and R^{L03}, or R^{L02} and R^{L03} represents a straight or branched alkylene group of 1 to 18 carbon atoms, preferably 1 to 10 carbon atoms when they form a ring.

In formula (L2), R^{L04}, R^{L05}, and R^{L06} are each independently a straight, branched or cyclic C₁-C₁₅ alkyl group. Suitable alkyl groups include methyl, ethyl, propyl, isopropyl, n-butyl, sec-butyl, tert-butyl, cyclopentyl, cyclohexyl, 2-ethylhexyl, n-octyl, 1-adamantyl, and 2-adamantyl.

In formula (L3), R^{L07} is an optionally substituted, straight, branched or cyclic C₁-C₁₀ alkyl group or optionally substituted C₆-C₂₀ aryl group. Examples of the optionally substituted alkyl groups include straight, branched or cyclic ones such as methyl, ethyl, propyl, isopropyl, n-butyl, sec-butyl, tert-butyl, tert-amyl, n-pentyl, n-hexyl, cyclopentyl, cyclohexyl, and bicyclo[2.2.1]heptyl; and substituted forms of the foregoing in which some hydrogen atoms are replaced by hydroxyl, alkoxy, carboxyl, alkoxycarbonyl, oxo, amino, alkylamino, cyano, mercapto, alkylthio, sulfo or other groups or in which one or more methylene moiety is replaced by an oxygen or sulfur atom. Exemplary optionally substituted aryl groups are phenyl, methylphenyl, naphthyl, anthryl, phenanthryl, and pyrenyl. In formula (L3), m is 0 or 1, n is 0, 1, 2 or 3, and 2 m+n is equal to 2 or 3.

In formula (L4), R^{L08} is an optionally substituted, straight, branched or cyclic C₁-C₁₀ alkyl group or optionally substituted C₆-C₂₀ aryl group. Examples are as exemplified for R^{L07}. R^{L09} to R^{L18} each independently denote hydrogen or a monovalent C₁-C₁₅ hydrocarbon group. Exemplary hydrocarbon groups are straight, branched or cyclic alkyl groups such as methyl, ethyl, propyl, isopropyl, n-butyl, sec-butyl, tert-butyl, tert-amyl, n-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl and cyclohexylbutyl, and substituted forms of the foregoing in which some hydrogen atoms are replaced by hydroxyl, alkoxy, carboxyl, alkoxycarbonyl, oxo, amino, alkylamino, cyano, mercapto, alkylthio, sulfo or other groups. Alternatively, a pair of R^{L09} and R^{L10}, R^{L09} and R^{L11}, R^{L09} and R^{L12}, R^{L10} and R^{L12}, R^{L11} and R^{L12}, R^{L13} and R^{L14}, R^{L15} and R^{L16}, or R^{L16} and R^{L17} may bond together to form a ring. Each of R^{L09} and R^{L10}, R^{L09} and R^{L11}, R^{L09} and R^{L12}, R^{L10} and R^{L12}, R^{L11} and R^{L12}, R^{L13} and R^{L14}, R^{L15} and R^{L14}, or R^{L16} and R^{L17} represents a divalent C₁-C₁₅ hydrocarbon group when they form a ring, examples of which are those exemplified above for the monovalent hydrocarbon groups, with one hydrogen atom being eliminated. Also a pair of R^{L09} and R^{L11}, R^{L11} and R^{L17}, or R^{L15} and R^{L17} which are attached to vicinal carbon atoms may bond together directly to form a double bond.

In formula (L5), R^{L19} is an optionally substituted, straight, branched or cyclic C₁-C₁₀ alkyl group or optionally substituted C₆-C₂₀ aryl group. Examples are as exemplified for R^{L07}.

In formula (L6), R^{L20} is an optionally substituted, straight, branched or cyclic C₁-C₁₀ alkyl group or optionally substituted C₆-C₂₀ aryl group. Examples are as exemplified for R^{L07}. X is a divalent group that forms an optionally substituted cyclopentane, cyclohexane or norbornane ring with the carbon atom to which it is attached. R^{L21} and R^{L22} are each independently hydrogen or a straight, branched or cyclic, monovalent hydrocarbon group of 1 to 10 carbon atoms. R^{L21} and R^{L22} may bond together to form a ring with the carbon atom to which they are attached, and in this case, R^{L21} and R^{L22} taken together represent a divalent group that forms an optionally substituted cyclopentane or cyclohexane ring. The subscript p is 1 or 2.

In formula (L7), R^{L22} is an optionally substituted, straight, branched or cyclic C₁-C₁₀ alkyl group or optionally substituted C₆-C₂₀ aryl group. Examples are as exemplified for R^{L07}. Y is a divalent group that forms an optionally substituted cyclopentane, cyclohexane or norbornane ring with the carbon atom to which it is attached. R^{L24} and R^{L25} are each independently hydrogen or a straight, branched or cyclic, monovalent hydrocarbon group of 1 to 10 carbon atoms. R^{L04} and R^{L25} may bond together to form a ring with the carbon atom to which they are attached, and in this case, R^{L24} and R^{L25} taken together represent a divalent group that forms an optionally substituted cyclopentane or cyclohexane ring. The subscript q is 1 or 2.

In formula (L8), R^{L26} is an optionally substituted, straight, branched or cyclic C₁-C₁₀ alkyl group or optionally substituted C₆-C₂₀ aryl group. Examples are as exemplified for R^{L07}. Z is a divalent group that forms an optionally substituted cyclopentane, cyclohexane or norbornane ring with the carbon atom to which it is attached. R^{L27} and R^{L28} are each independently hydrogen or a straight, branched or cyclic, monovalent hydrocarbon group of 1 to 10 carbon atoms. R^{L27} and R^{L28} may bond together to form a ring with the carbon atom to which they are attached, and in this case, R^{L27} and R^{L28} taken together represent a divalent group that forms an optionally substituted cyclopentane or cyclohexane ring.

Of the acid labile groups of formula (L1), the straight and branched ones are exemplified by the following groups.

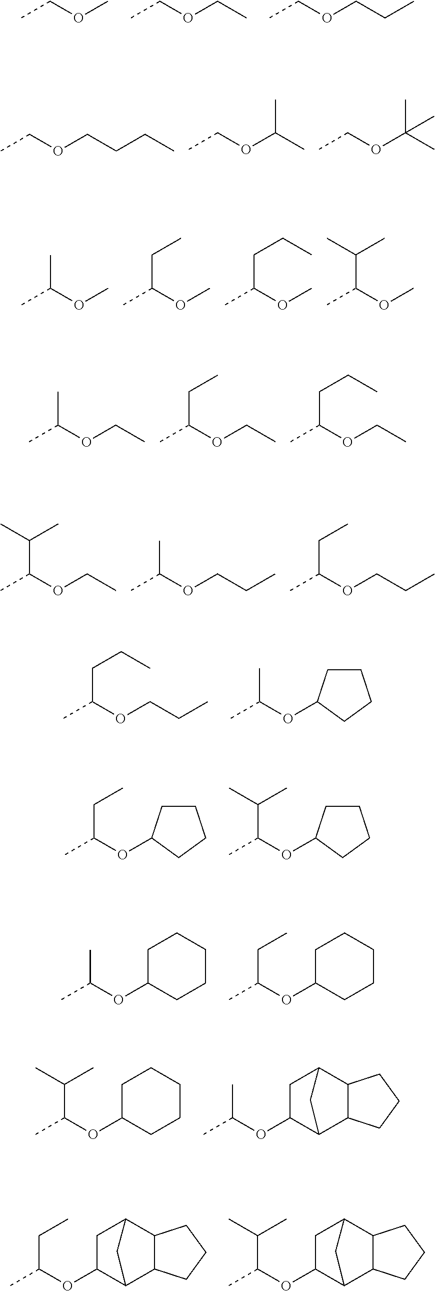

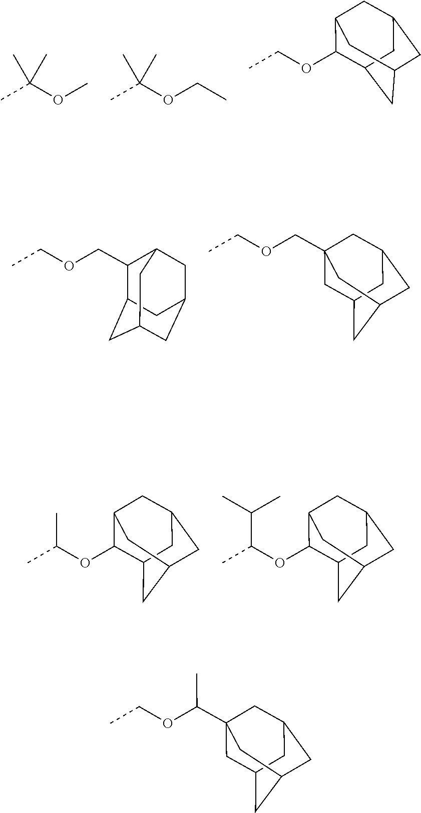

Of the acid labile groups of formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile group of formula (L2) include tert-butyl, tert-amyl, and the groups shown below.

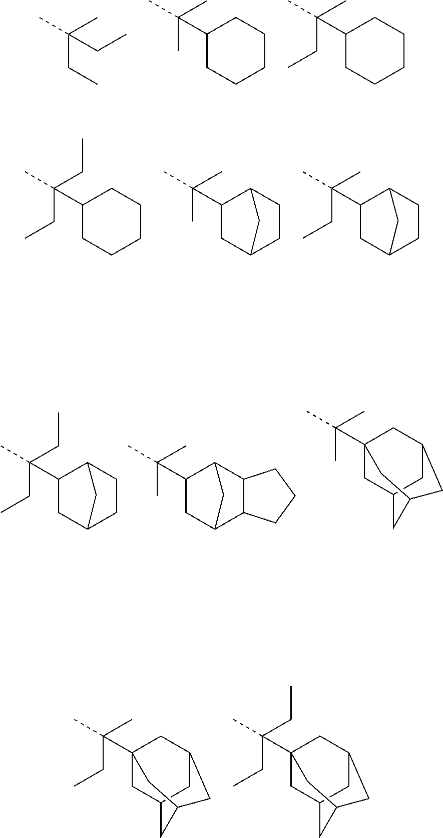

Examples of the acid labile groups of formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxy-n-butyl)cyclopentyl, 1-(bicyclo[2.2.1]heptan-2-yl)cyclopentyl, 1-(7-oxabicyclo[2.1.1]heptan-2-yl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl.

Of the acid labile groups of formula (L4), those groups of the following formulae (L4-1) to (L4-4) are more preferred.

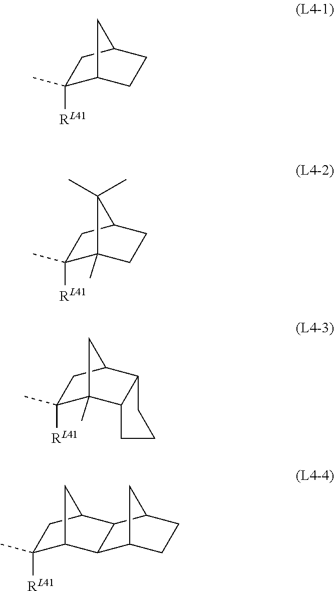

In formulae (L4-1) to (L4-4), the broken line denotes a bonding site and direction. R^{L41} is each independently selected from monovalent hydrocarbon groups, typically straight, branched or cyclic C₁-C₁₀ alkyl groups, for example, methyl, ethyl, propyl, isopropyl, n-butyl, sec-butyl, tert-butyl, tert-amyl, n-pentyl, n-hexyl, cyclopentyl, and cyclohexyl.

For formulas (L4-1) to (L4-4), there can exist enantiomers and diastereomers. Each of formulae (L4-1) to (L4-4) collectively represents all such stereoisomers. Such stereoisomers may be used alone or in admixture.

For example, the general formula (L4-3) represents one or a mixture of two selected from groups having the following general formulas (L4-3-1) and (L4-3-2).

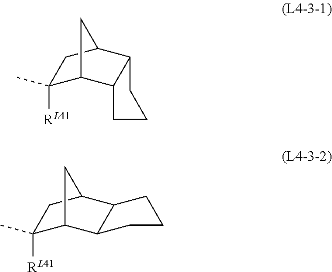

Herein R^{L41} is as defined above.

Similarly, the general formula (L4-4) represents one or a mixture of two or more selected from groups having the following general formulas (L4-4-1) to (L4-4-4).

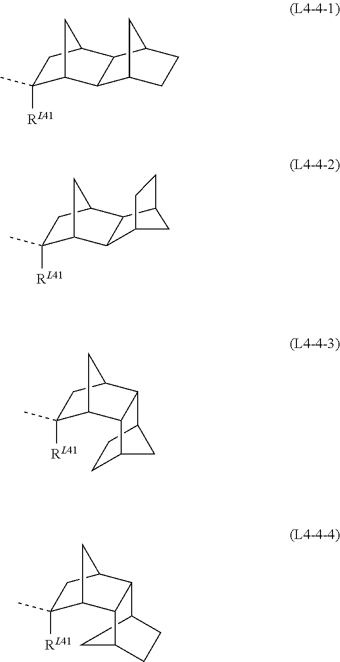

Herein R^{L41} is as defined above.

Each of formulas (L4-1) to (L4-4), (L4-3-1) and (L4-3-2), and (L4-4-1) to (L4-4-4) collectively represents an enantiomer thereof and a mixture of enantiomers.

It is noted that in the above formulas (L4-1) to (L4-4), (L4-3-1) and (L4-3-2), and (L4-4-1) to (L4-4-4), the bond direction is on the exo side relative to the bicyclo[2.2.1]heptane ring, which ensures high reactivity for acid catalyzed elimination reaction (see JP-A 2000-336121). In preparing these monomers having a tertiary exo-alkyl group of bicyclo[2.2.1]heptane skeleton as a substituent group, there may be contained monomers substituted with an endo-alkyl group as represented by the following formulas (L4-1-endo) to (L4-4-endo). For good reactivity, an exo proportion of at least 50 mol % is preferred, with an exo proportion of at least 80 mol % being more preferred.

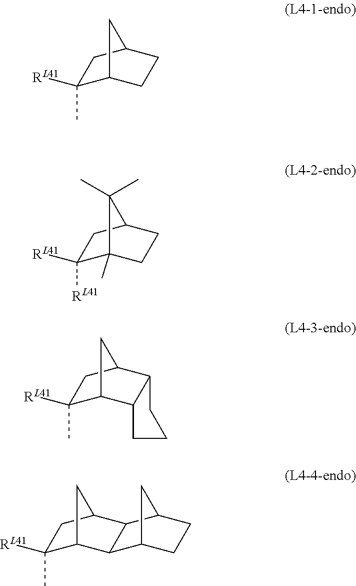

Herein R^{L41} is as defined above.

Illustrative examples of the acid labile group of formula (L4) are given below, but not limited thereto.

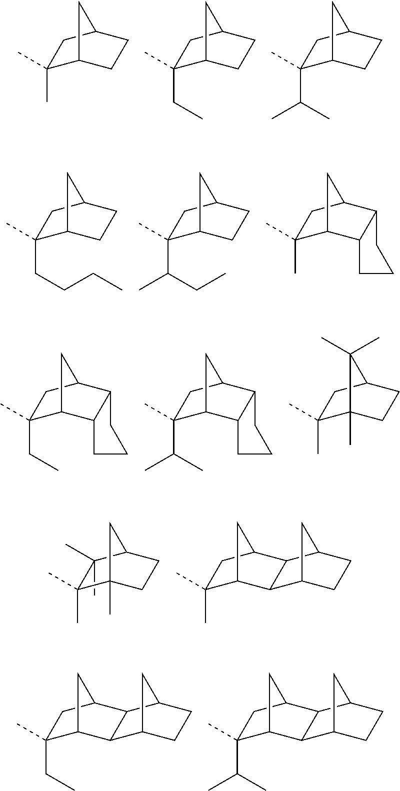

Examples of the acid labile group of formula (L5) are shown below.

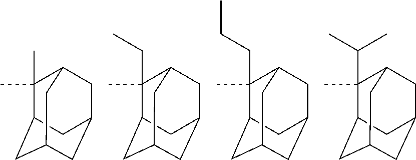

Examples of the acid labile group of formula (L6) are shown below.

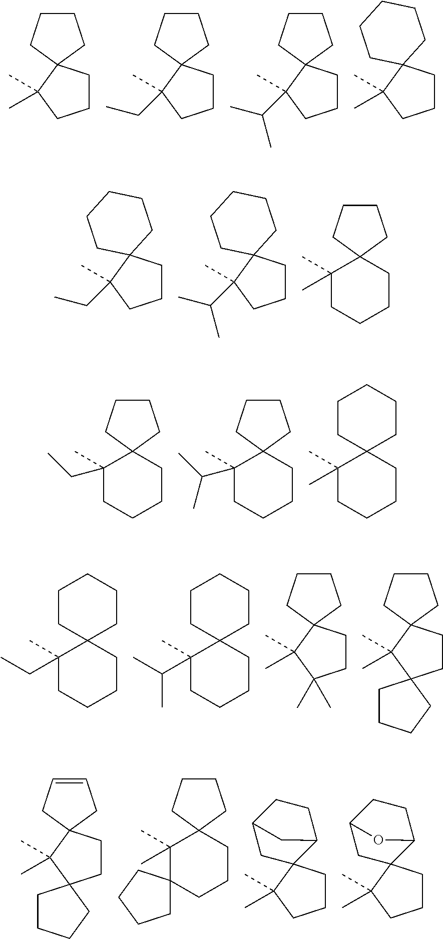

Examples of the acid labile group of formula (L7) are shown below.

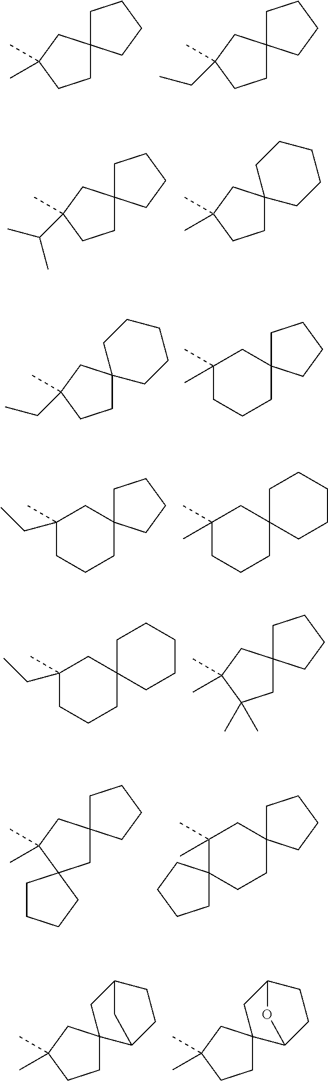

Examples of the acid labile group of formula (L8) are shown below.

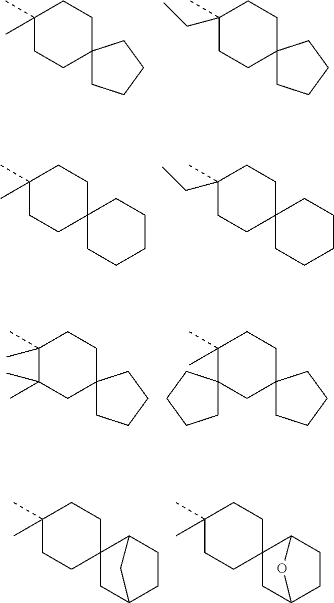

Illustrative, non-limiting examples of the acid labile unit of the structure represented by formula (3) and having an acid labile group as exemplified above are shown below.

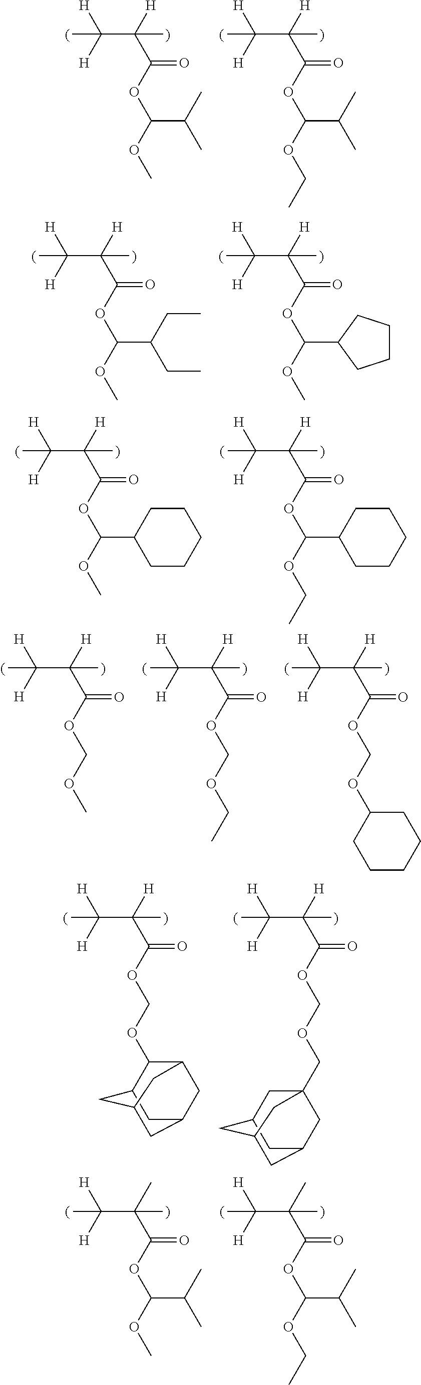

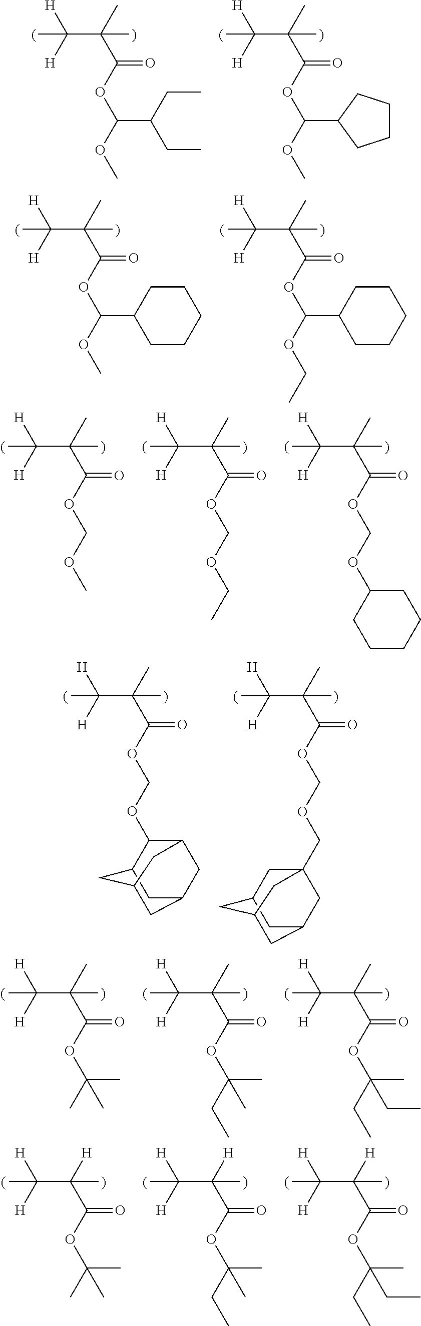

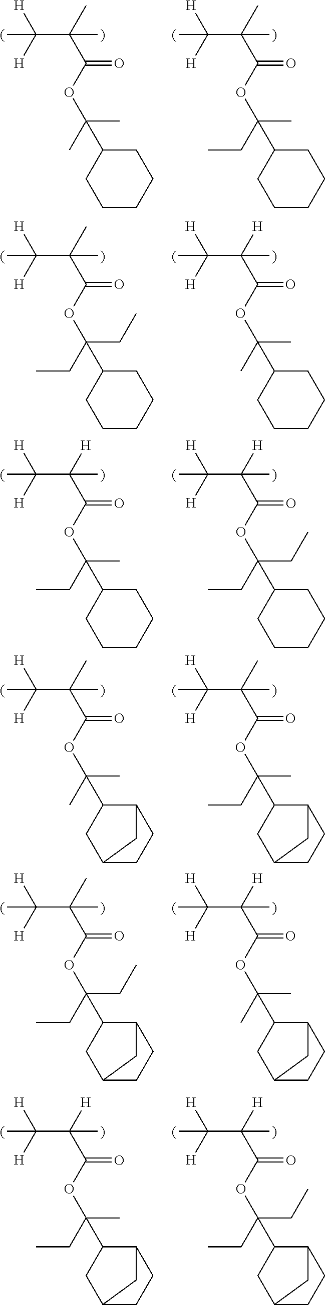

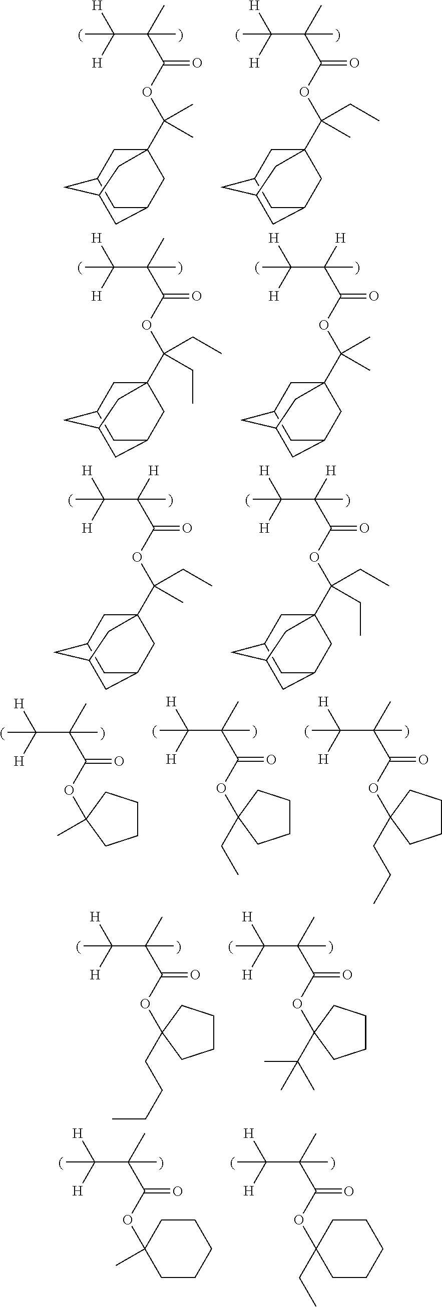

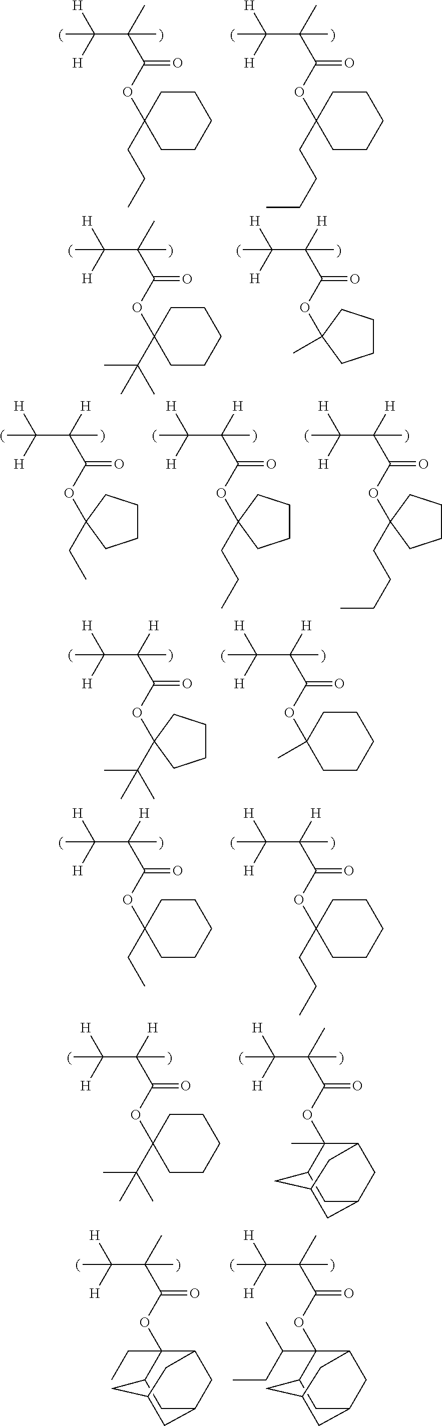

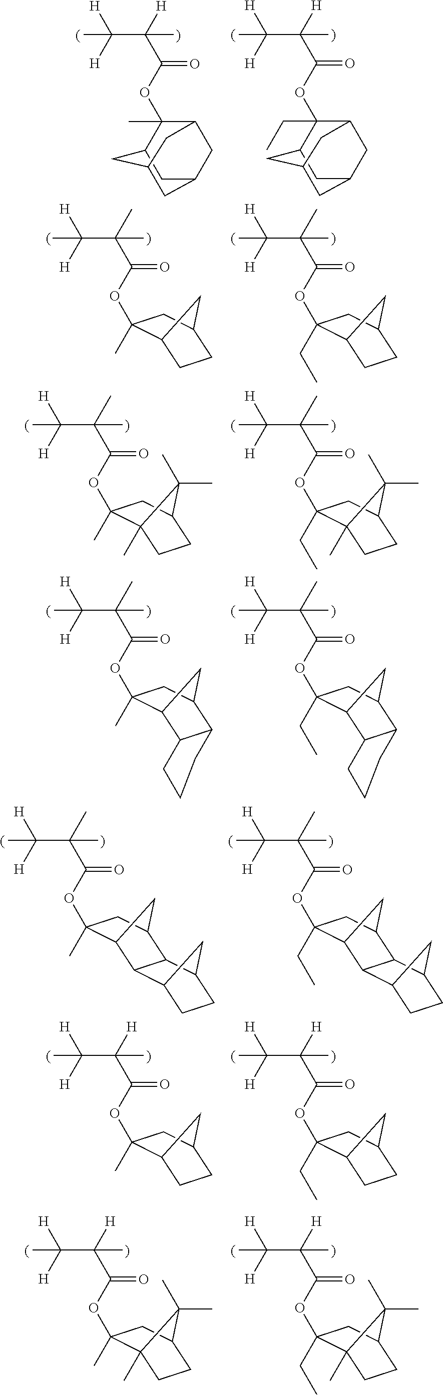

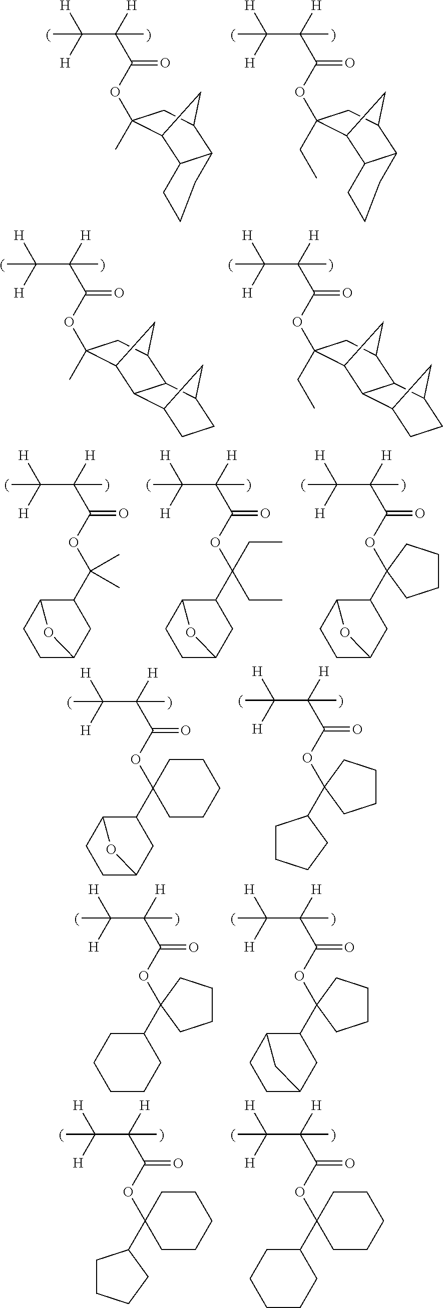

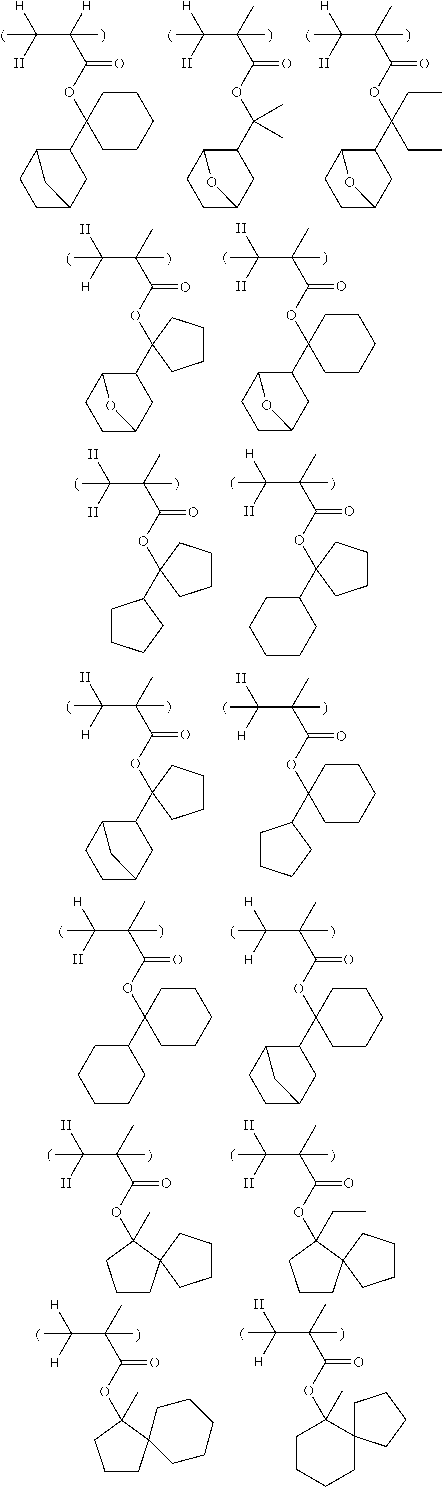

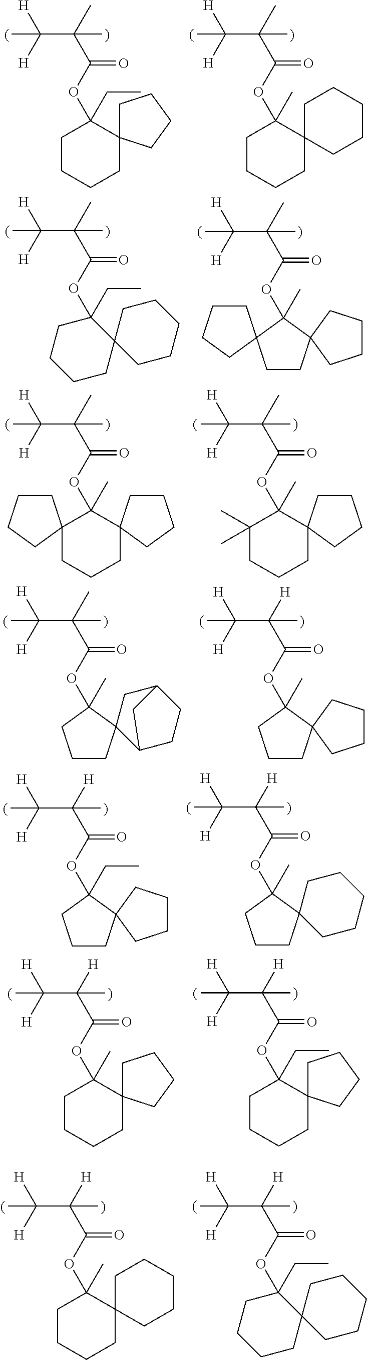

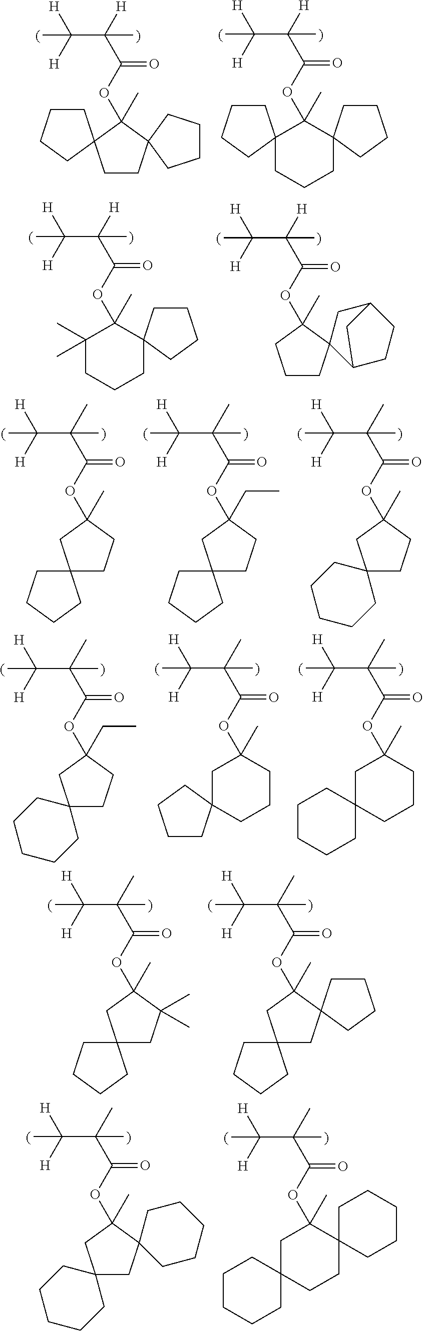

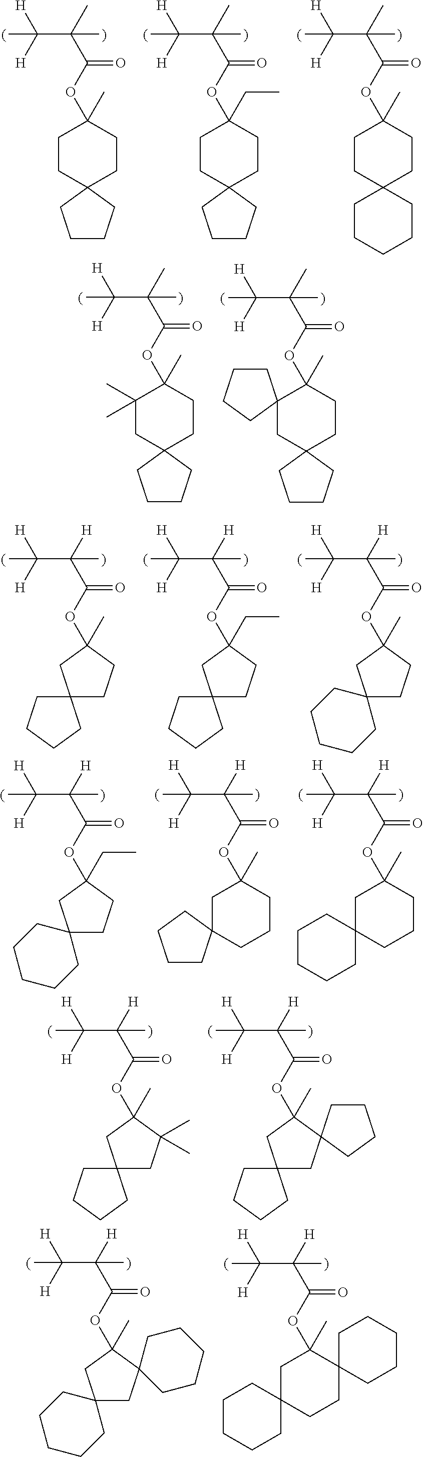

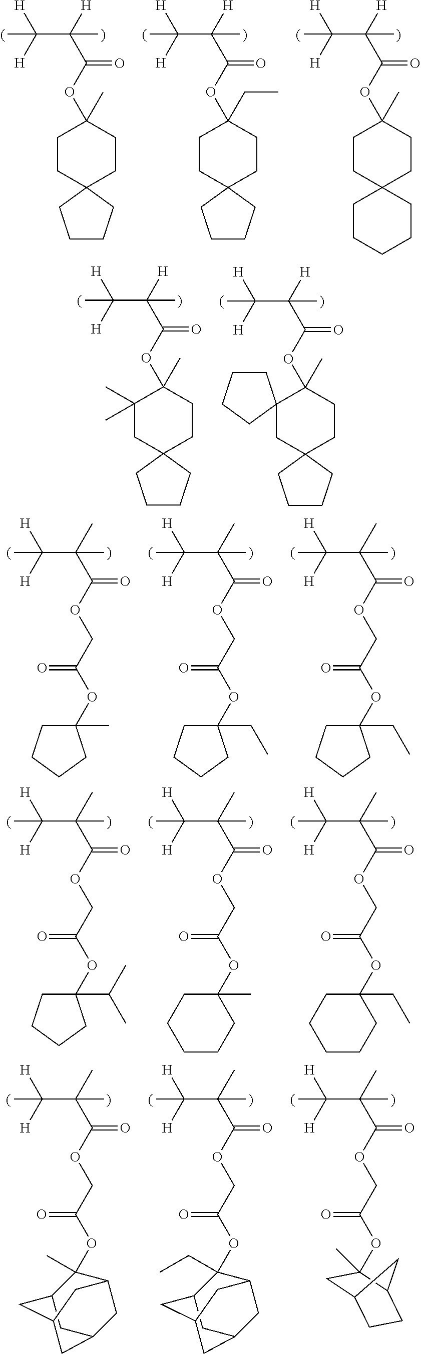

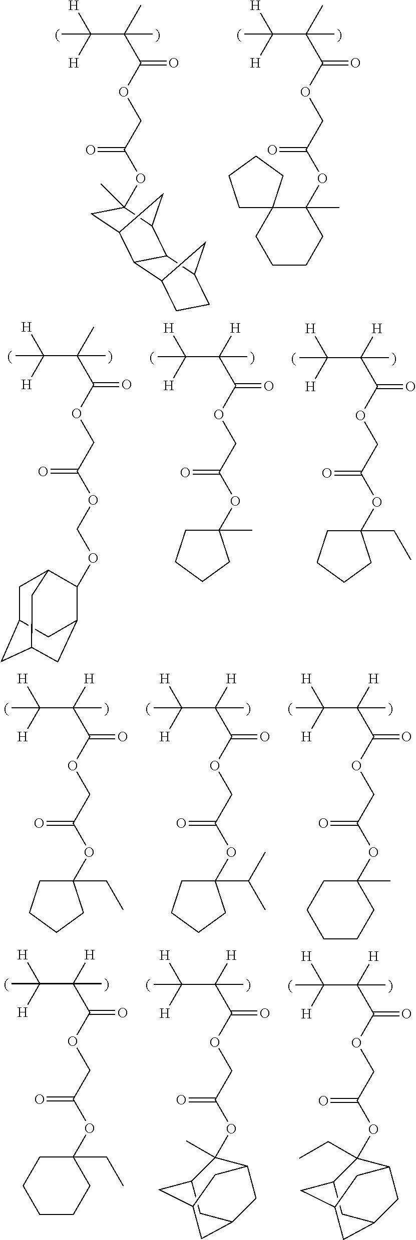

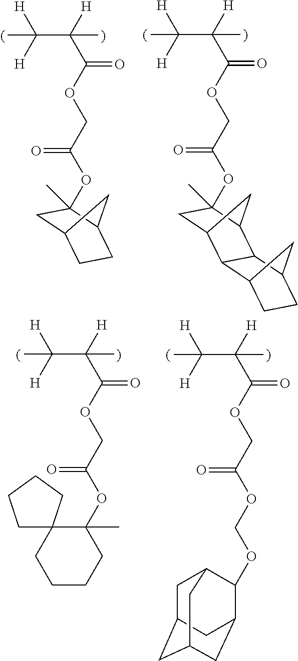

The polymer is characterized by comprising recurring units of a structure adapted to generate an acid in response to high-energy radiation, having formula (1a) and/or (1b), recurring units of a lactone ring-containing structure having formula (2a) and/or (2b), and acid labile units having formula (3) as essential units, wherein all the units are free of hydroxyl.

The polymer should be free of any hydroxyl-containing units independent of whether they are acidic or non-acidic. The following structures are exemplary of the recurring units that should not be contained herein.

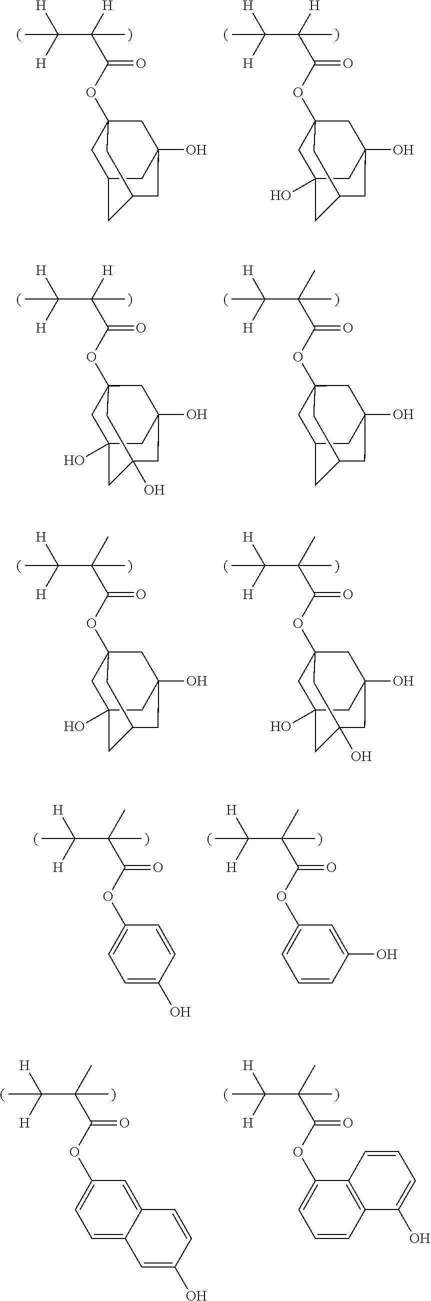

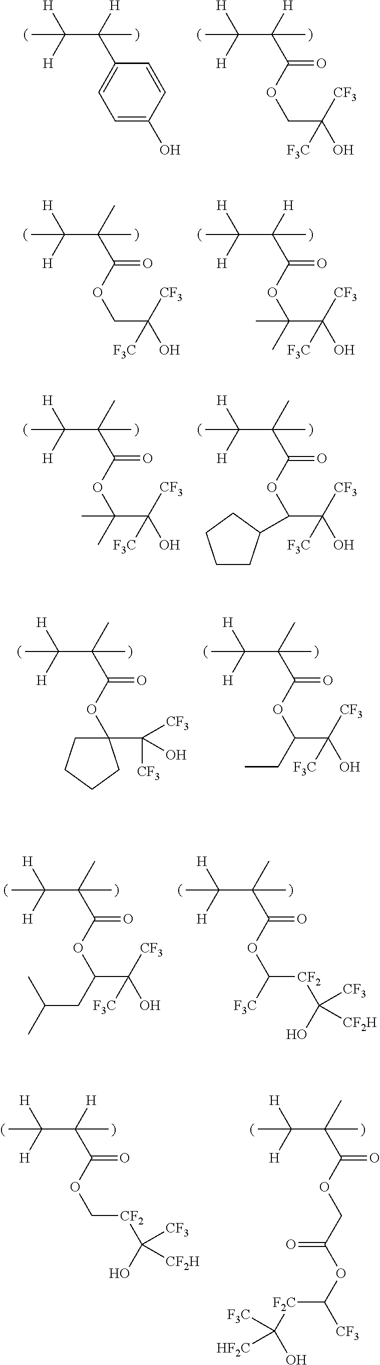

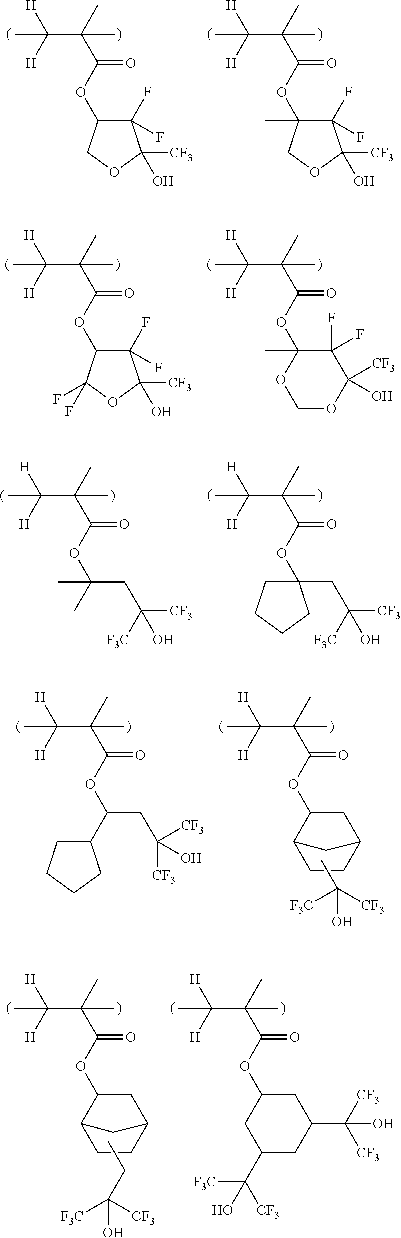

While the polymer is characterized by comprising recurring units of a structure adapted to generate an acid in response to high-energy radiation, having formula (1a) and/or (1b), recurring units of a lactone ring-containing structure having formula (2a) and/or (2b), and acid labile units having formula (3) as essential units, wherein all the units are free of hydroxyl, the polymer may further comprise additional recurring units as long as they are free of hydroxyl. For example, aside from the lactone ring-containing units of formula (2a) and/or (2b), lactone ring-containing units of different structure may be further incorporated. Illustrative, non-limiting examples of additional lactone ring-containing units are shown below.

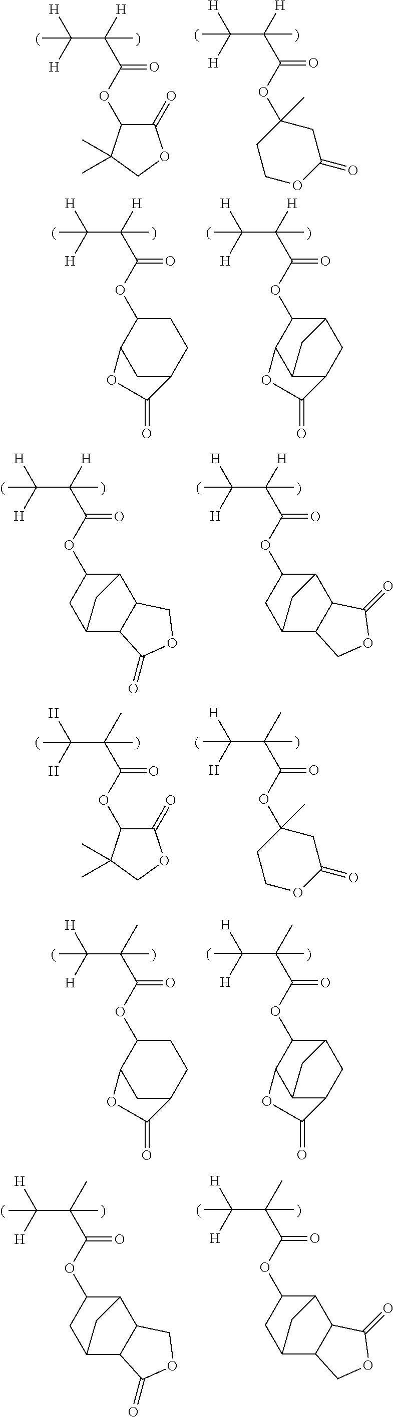

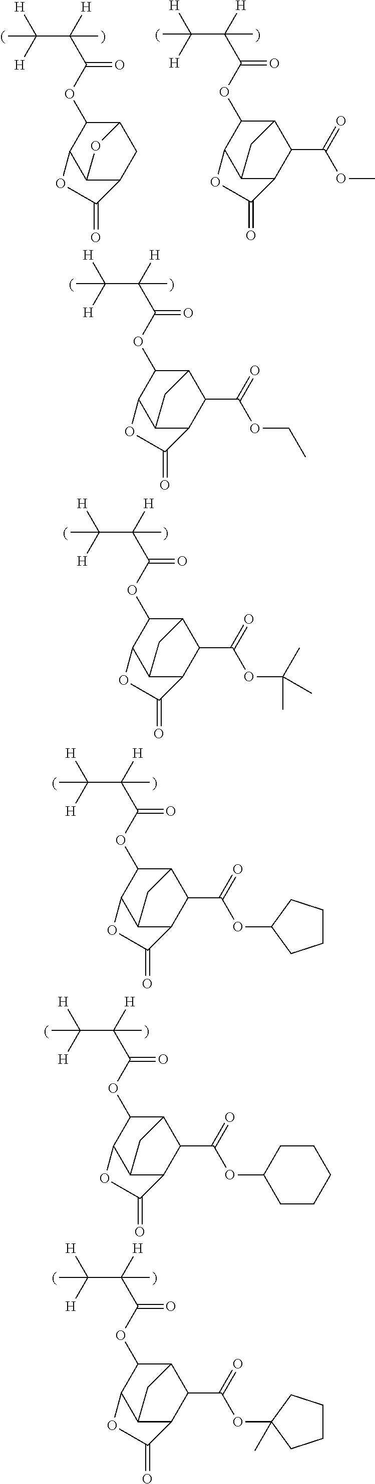

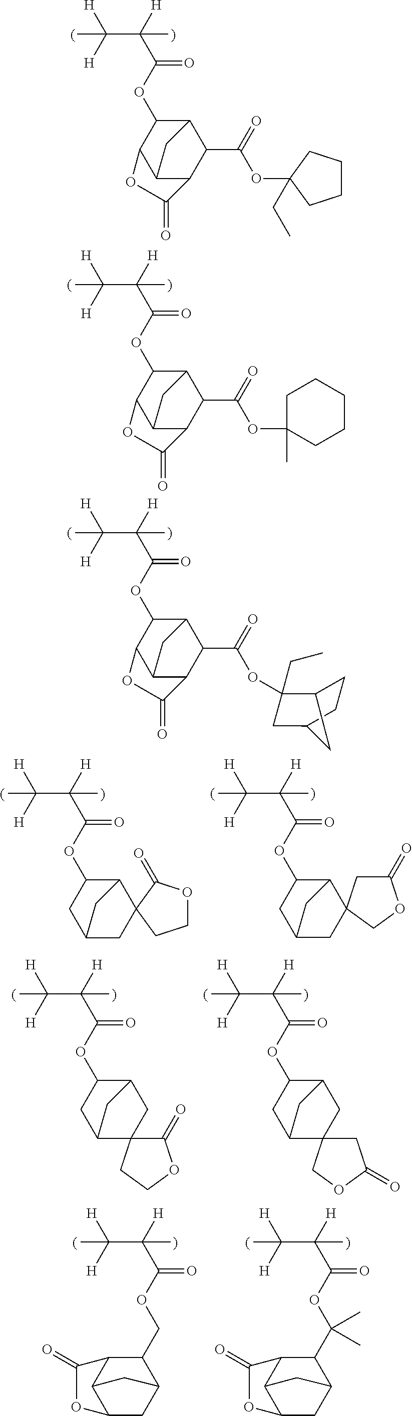

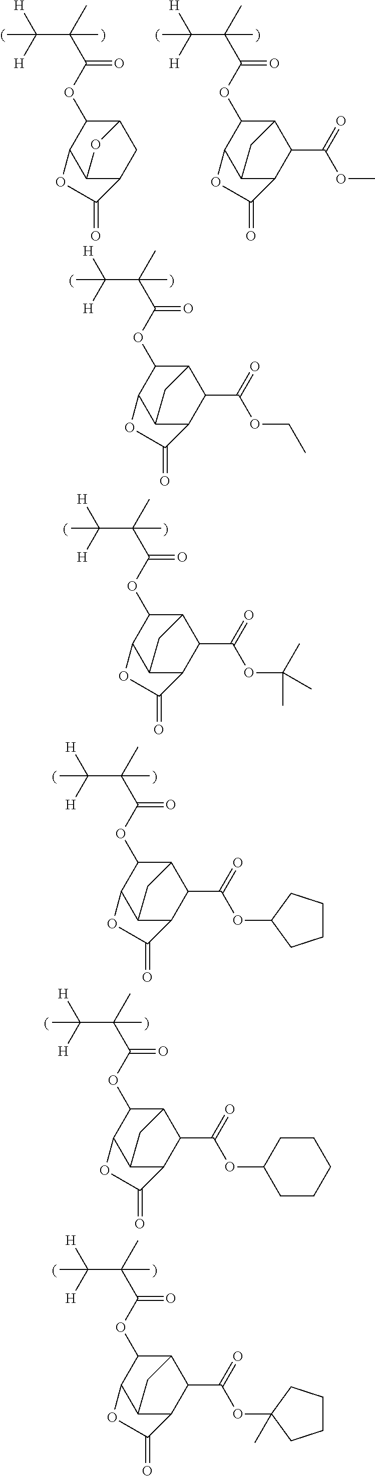

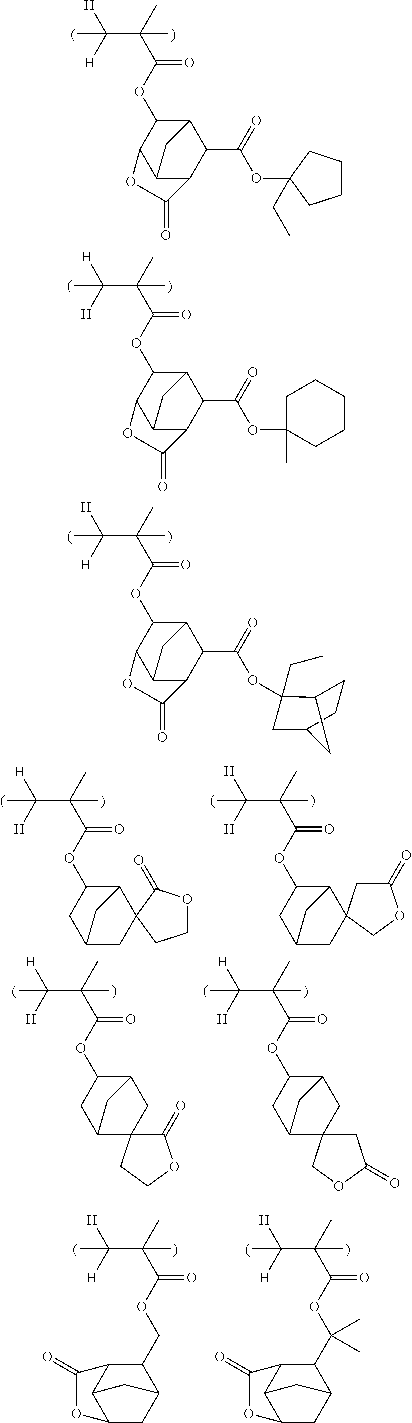

If desired, the polymer may further comprise additional recurring units other than the lactone ring-containing units as long as these units are free of hydroxyl. The additional recurring units which can be incorporated herein are typically units containing a carboxyl or fluoroalkyl group, examples of which are shown below. Where carboxyl-containing units are incorporated, their content should preferably be up to 10 mol % based on the overall recurring units because a higher content of carboxyl-containing units can degrade the rectangularity of a pattern or allow for swelling to detract from pattern collapse resistance. As long as the content is up to 10 mol %, the carboxyl-containing units may be advantageous for controlling the dissolution rate without raising such a problem.

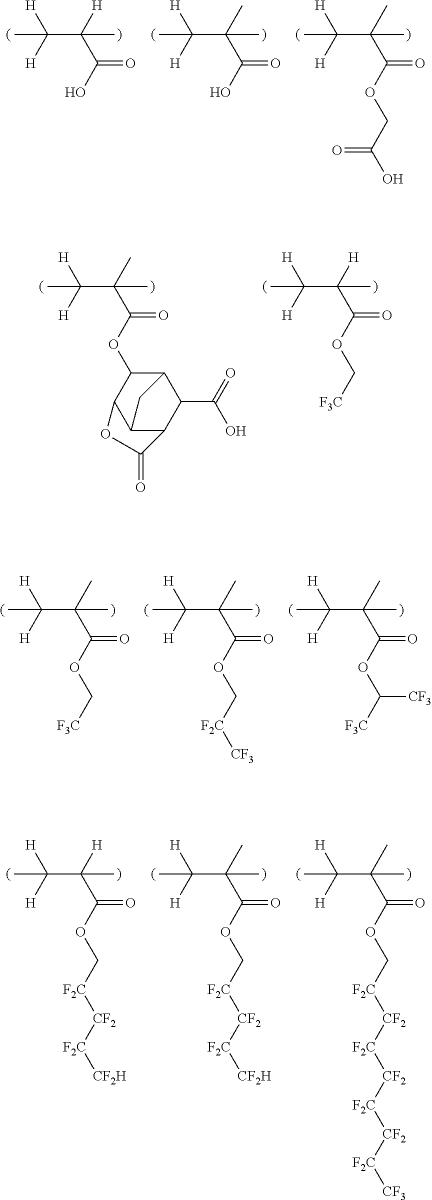

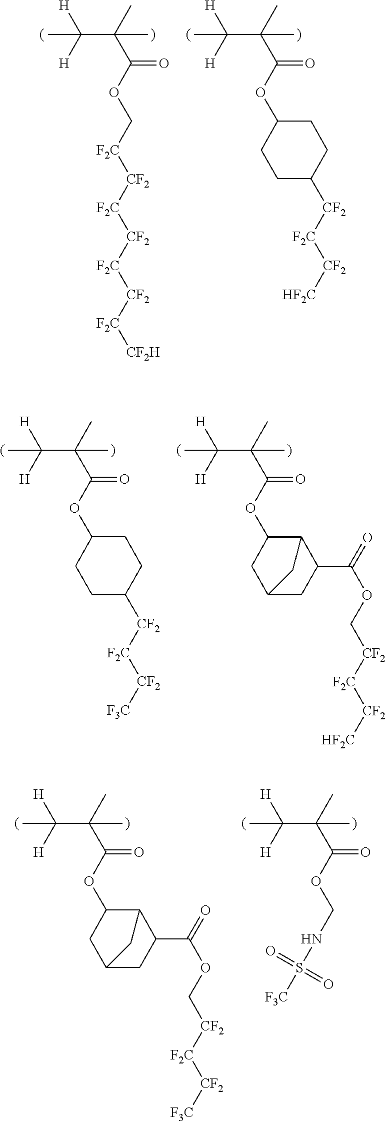

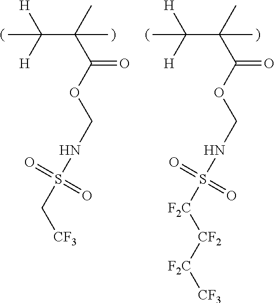

The compositional ratio of recurring units of which the polymer is constructed is preferably in the following range. Provided that a total content of recurring units of a structure adapted to generate an acid in response to high-energy radiation, having formula (1a) and/or (1b) is “a” mol %, a total content of recurring units of a lactone ring-containing structure having formula (2a) and/or (2b) is “b” mol %, a total content of acid labile units having formula (3) is “c” mol %, a total content of lactone-containing units other than the structure of formula (2a) or (2b) is “d” mol %, and a total content of additional recurring units is “e” mol %, and a+b+c+d+e=100 mol %, the compositional ratio is preferably in the range:

0≦a≦30, 0≦b≦80, 0≦c≦80, 0≦d≦50, and 0≦e≦10,
and more preferably
1≦a≦10, 20≦b≦60, 20≦c≦60, 0≦d≦40, and 0≦e≦5.

The polymer preferably has a weight average molecular weight (Mw) of 1,000 to 500,000, and more preferably 2,000 to 30,000 as measured by gel permeation chromatography (GPC) versus polystyrene standards. Outside the range, a polymer with a lower Mw is likely to dissolve in water whereas a polymer with a higher Mw has strong possibilities of alkali solubility being lost and defects being formed upon spin coating.

The polymer may be prepared through copolymerization reaction using a monomer having formula (1a′) and/or (1b′), a monomer having formula (2a′) and/or (2b′), a monomer having formula (3′), and optionally another monomer having a polymerizable double bond. Although various modes of copolymerization reaction may be used for the preparation of the polymer, radical polymerization is preferred.

For radical polymerization, preferred reaction conditions include (a) a solvent selected from hydrocarbon solvents such as benzene, ether solvents such as tetrahydrofuran, alcohol solvents such as ethanol, and ketones such as methyl isobutyl ketone; (b) a polymerization initiator selected from azo compounds such as 2,2′-azobisisobutyronitrile and peroxides such as benzoyl peroxide and lauroyl peroxide; (c) a reaction temperature in the range of about 0° C. to about 100° C.; and (d) a reaction time in the range of about 0.5 to about 48 hours. Reaction parameters outside these ranges need not be excluded.

### Resist Composition

The polymer of the invention is advantageously used as a base resin in a positive resist composition. Thus a second embodiment of the invention is a positive resist composition comprising the polymer. The positive resist composition preferably comprises:

(A) a base resin comprising the inventive polymer,

(C) an organic solvent, and optionally,

(B) an acid generator,

(D) a quencher, and

(E) a surfactant.

For the positive resist composition, the base resin as component (A) may comprise another resin having a dissolution rate in an alkaline developer that increases under the action of an acid, if desired, as well as the inventive polymer. Exemplary other resins include, but are not limited to, (i) poly(meth)acrylic acid derivatives, (ii) norbornene derivative/maleic anhydride copolymers, (iii) hydrogenated products of ring-opening metathesis polymerization (ROMP) polymers, (iv) vinyl ether/maleic anhydride/(meth)acrylic acid derivative copolymers, and (v) polyhydroxystyrene derivatives.

Among others, hydrogenated products of ROMP polymers are synthesized by the method of JP-A 2003-66612. Illustrative, non-limiting examples of the ROMP polymers include those having the following recurring units.

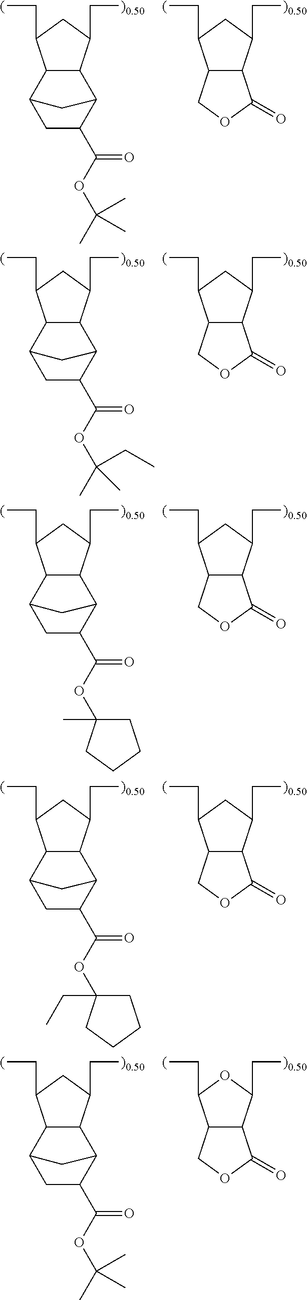

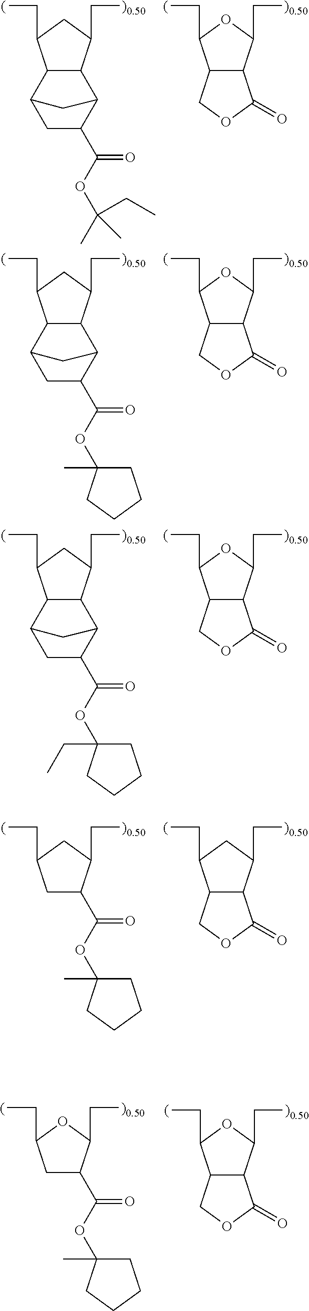

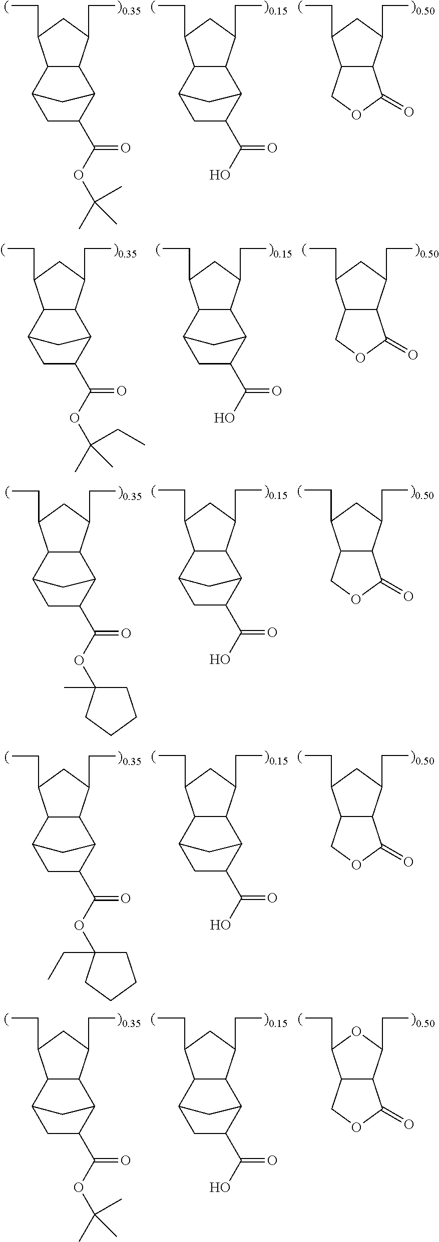

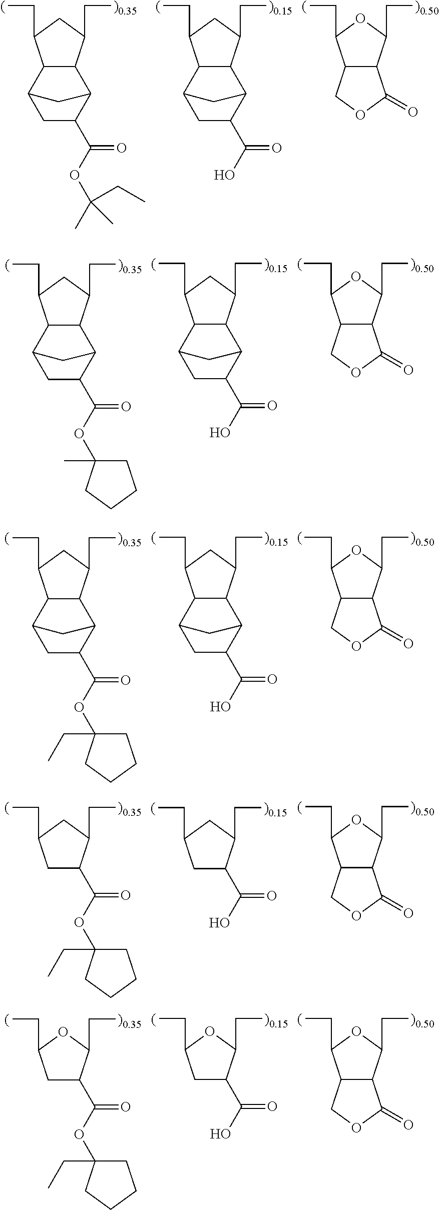

The inventive polymer and the other polymer are preferably blended in a weight ratio from 100:0 to 30:70, more preferably from 100:0 to 50:50. If the blend ratio of the inventive polymer is below this range, the resist composition may become poor in some of the desired properties. The performance of the resist composition can be adjusted by properly changing the blend ratio of the inventive polymer. The other polymer is not limited to one type and a mixture of two or more polymers may be added. The use of plural polymers allows for easy adjustment of resist properties.

In the practice of the invention, an acid generator is optionally used as component (B). Where a photoacid generator is added as the acid generator, it may be any compound capable of generating an acid upon exposure to high-energy radiation. Suitable PAGs include sulfonium salts, iodonium salts, sulfonyldiazomethane, N-sulfonyloxyimide, and oxime-O-sulfonate acid generators. Exemplary PAGs are given in JP-A 2009-269953 (US 20090274978).

Preferred among others are those acid generators having the general formula (F) as described in JP-A 2009-269953.

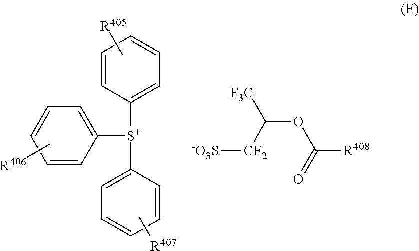

Herein R⁴⁰⁵, R⁴⁰⁶ and R⁴⁰⁷ are each independently hydrogen or a monovalent, straight, branched or cyclic C₁-C₂₀ hydrocarbon group which may contain a heteroatom, preferably an alkyl or alkoxy group. Examples of the hydrocarbon group which may contain a heteroatom include methyl, ethyl, propyl, isopropyl, n-butyl, sec-butyl, tert-butyl, tert-amyl, n-pentyl, n-hexyl, cyclopentyl, cyclohexyl, ethylcyclopentyl, butylcyclopentyl, ethylcyclohexyl, butylcyclohexyl, adamantyl, ethyladamantyl, butyladamantyl, and modified forms of the foregoing in which any carbon-carbon bond is interrupted by a heteroatom group such as —O—, —S—, —SO—, —SO₂—, —NH—, —C(═O)—, —C(═O)O—, or —C(═O)NH—, or any hydrogen atom is replaced by a functional group such as —OH, —NH₂, —CHO, or —CO₂H. R⁴⁰⁸ is a monovalent, straight, branched or cyclic C₇-C₃₀ hydrocarbon group which may contain a heteroatom.

In the positive resist composition, the PAG (B) may be added in any desired amount as long as the objects of the invention are not compromised. An appropriate amount of the PAG is 0.1 to 30 parts, and more preferably 1 to 20 parts by weight per 100 parts by weight of the base resin in the composition. Too high a proportion of the PAG may give rise to problems of degraded resolution and foreign matter upon development and resist film peeling. The PAGs may be used alone or in admixture of two or more. The transmittance of the resist film can be controlled by using a PAG having a low transmittance at the exposure wavelength and adjusting the amount of the PAG added.

It is noted that an acid diffusion controlling function may be provided when the PAG is an onium salt capable of generating a weak acid. Specifically, in a system using the inventive polymer capable of generating a strong acid in combination with an onium salt capable of generating a weak acid (e.g., non-fluorinated sulfonic acid or carboxylic acid), if the strong acid generated from the inventive polymer upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion.

If an onium salt capable of generating a strong acid and an onium salt capable of generating a weak acid are used in admixture, an exchange from the strong acid to the weak acid as above can take place, but it never happens that the weak acid collides with the unreacted onium salt capable of generating a strong acid to induce a salt exchange. This is because of a likelihood of an onium cation forming an ion pair with a stronger acid anion.

A quencher (D) may be optionally used in the resist composition. The term “quencher” as used herein has a meaning generally known in the art and refers to a compound capable of suppressing the rate of diffusion when the acid generated by the acid generator diffuses within the resist film. The inclusion of quencher facilitates adjustment of resist sensitivity and holds down the rate of acid diffusion within the resist film, resulting in better resolution. In addition, it suppresses changes in sensitivity following exposure and reduces substrate and environment dependence, as well as improving the exposure latitude and the pattern profile. Examples of suitable quenchers include primary, secondary, and tertiary aliphatic amines, mixed amines, aromatic amines, heterocyclic amines, nitrogen-containing compounds with carboxyl group, nitrogen-containing compounds with sulfonyl group, nitrogen-containing compounds with hydroxyl group, nitrogen-containing compounds with hydroxyphenyl group, alcoholic nitrogen-containing compounds, amide derivatives, imide derivatives, carbamate derivatives, and ammonium salts. Exemplary quenchers are given in JP-A 2009-269953.

The quencher is preferably formulated in an amount of 0.001 to 8 parts, and especially 0.01 to 5 parts by weight, per 100 parts by weight of the base resin. Less than 0.001 phr of the quencher may achieve no addition effect whereas more than 8 phr may lead to too low a sensitivity.

In the resist composition, a compound which is decomposed with an acid to generate another acid, that is, acid amplifier compound may be added. For these compounds, reference should be made to JP-A 2009-269953. In the resist composition, an appropriate amount of the acid amplifier compound added is up to 2 parts, and especially up to 1 part by weight per 100 parts by weight of the base resin. Excessive amounts of the acid amplifier compound make diffusion control difficult, leading to degradation of resolution and pattern profile.

In the resist composition, an organic acid derivative or a compound having a Mw of up to 3,000 which changes solubility in alkaline developer under the action of an acid, known as dissolution inhibitor, may be added. With respect to these components, reference should be made to JP-A 2009-269953.

The organic solvent (C) used herein may be any organic solvent in which the base resin, acid generator, and other components are soluble. Illustrative, non-limiting, examples of the organic solvent include ketones such as cyclohexanone and methyl-2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone. These solvents may be used alone or in combinations of two or more. Of the above organic solvents, it is recommended to use diethylene glycol dimethyl ether, 1-ethoxy-2-propanol, PGMEA, and mixtures thereof because the acid generator is most soluble therein.

An appropriate amount of the organic solvent used is 200 to 4,000 parts, especially 400 to 3,000 parts by weight per 100 parts by weight of the base resin.

Optionally, the resist composition may further comprise (E) a surfactant. With respect to the surfactant, reference should be made to JP-A 2009-269953. Reference may also be made to JP-A 2008-122932, JP-A 2010-134012, JP-A 2010-107695, JP-A 2009-276363, JP-A 2009-192784, JP-A 2009-191151, and JP-A 2009-098638. Any of conventional surfactants and alkali soluble surfactants may be used.

An appropriate amount of the surfactant added is 0.001 to 20 parts, more preferably 0.01 to 10 parts by weight per 100 parts by weight of the base resin. With respect to the amount, reference should be made to JP-A 2007-297590.

### Process

A third embodiment is a pattern forming process using the resist composition described above. Pattern formation using the resist composition of the invention may be performed by well-known lithography processes. The process generally involves coating, prebaking, exposure, optional PEB, and development. If necessary, any additional steps may be added.

First the resist composition is applied onto a substrate for integrated circuitry fabrication (e.g., Si, SiO₂, SiN, SiON, TiN, WSi, BPSG, SOG, organic antireflective film, etc.) or a substrate for mask circuitry fabrication (e.g., Cr, CrO, CrON, MoSi, etc.) by a suitable coating technique such as spin coating. The coating is prebaked on a hot plate at a temperature of 60 to 150° C. for 1 to 10 minutes, preferably 80 to 140° C. for 1 to 5 minutes. The resulting resist film is generally 0.05 to 2.0 μm thick. Through a photomask having a desired pattern disposed over the substrate, the resist film is then exposed to high-energy radiation such as deep-UV, excimer laser or x-ray, or electron beam in an exposure dose preferably in the range of 1 to 200 mJ/cm², more preferably 10 to 100 mJ/cm². Alternatively, pattern formation may be performed by writing with an electron beam directly (not through a mask). Light exposure may be done by a conventional exposure process or in some cases, by an immersion process of providing liquid impregnation between the mask and the resist. In the case of immersion lithography, a protective coating which is insoluble in water may be used. The resist film is then post-exposure baked (PEB) on a hot plate at 60 to 150° C. for 1 to 5 minutes, and preferably at 80 to 140° C. for 1 to 3 minutes. Finally, development is carried out using as the developer an aqueous alkali solution, such as a 0.1 to 5 wt %, preferably 2 to 3 wt %, aqueous solution of tetramethylammonium hydroxide (TMAH), this being done by a conventional method such as dip, puddle, or spray development for a period of 0.1 to 3 minutes, and preferably 0.5 to 2 minutes. In this way the desired pattern is formed on the substrate. Of the various types of high-energy radiation that may be used, the resist composition of the invention is best suited to fine pattern formation with, in particular, deep-UV or excimer laser having a wavelength of 250 to 180 nm, x-ray, or electron beam. The desired pattern may not be obtainable outside the upper and lower limits of the above range.

The water-insoluble protective coating which is used in the immersion lithography is to prevent the resist film from being leached and to improve water slippage at the film surface and is generally divided into two types. The first type is an organic solvent-strippable protective coating which must be stripped, prior to alkaline development, with an organic solvent in which the resist film is not dissolvable. The second type is an alkali-soluble protective coating which is soluble in an alkaline developer so that it can be removed simultaneously with the removal of solubilized areas of the resist film. The protective coating of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a solution, from which the protective coating of the second type is formed.

### EXAMPLE

Synthesis Examples, Examples and Comparative Examples are given below by way of illustration and not by way of limitation. Weight average molecular weight (Mw) and number average molecular weight (Mn) are measured by gel permeation chromatography (GPC), and a dispersity (Mw/Mn) is computed therefrom.

### Synthesis Examples 1 to 7

Synthesis of Monomers

A polymerizable monomer from which recurring units capable of generating an acid in response to energy radiation are derived was synthesized according to the teaching of JP-A 2008-133448 (U.S. Pat. No. 7,569,326). In this way, Monomers 1 to 7 were obtained, whose structure is shown below.

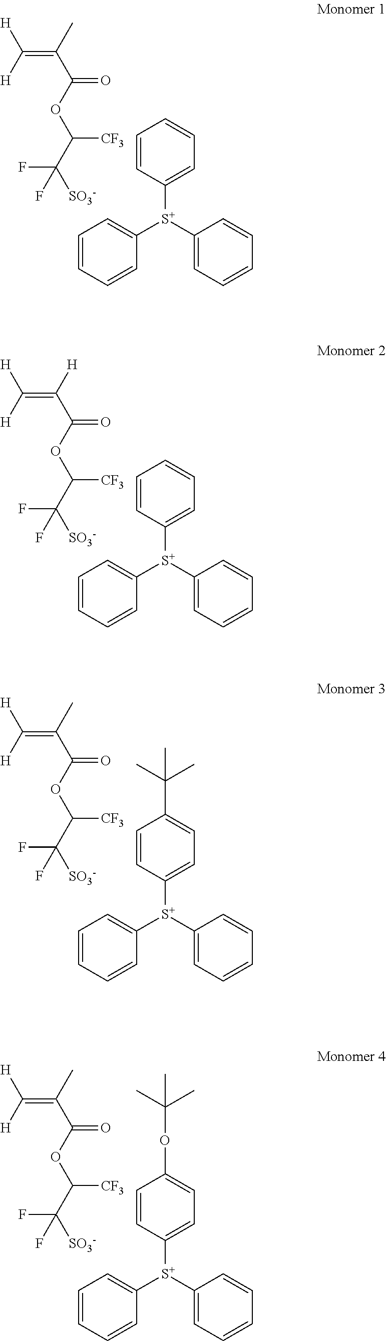

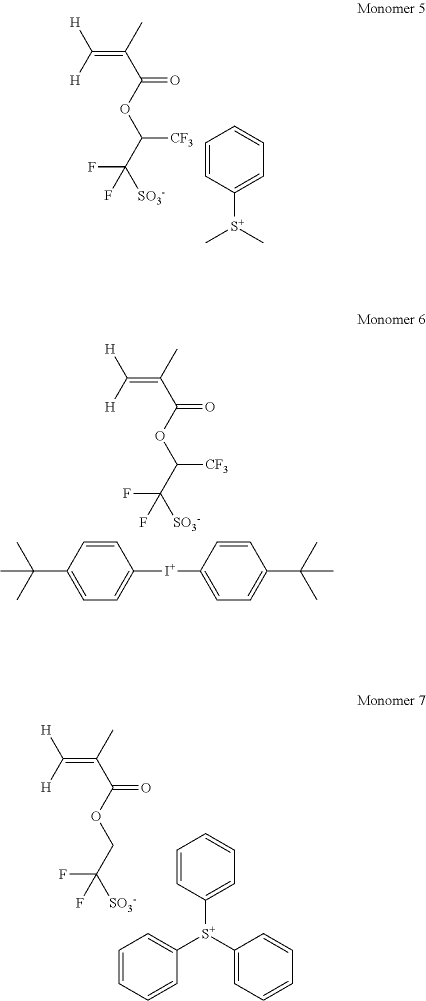

### Example 1-1

Synthesis of Polymer 1

A flask in nitrogen blanket was charged with 3.99 g of Monomer 1 in Synthesis Example 1, 20.01 g of 4-ethyltetracyclo[6.2.1.1^{3,6}.0^{2,7}]dodecanyl methacrylate, 13.79 g of 2-oxotetrahydrofuran-3-yl methacrylate, 1.11 g of 2,2′-azobisisobutyronitrile, and 70.0 g of methyl ethyl ketone (MEK) to form a monomer solution. Another flask in nitrogen blanket was charged with 23.0 g of MEK and heated at 80° C. with stirring, to which the monomer solution was added dropwise over 4 hours. After the completion of dropwise addition, the reaction solution was stirred for 2 hours for polymerization while maintaining the temperature of 80° C., and then cooled to room temperature. With vigorous stirring, the polymerization solution was added dropwise to 400 g of hexane whereupon a copolymer precipitate was collected by filtration. The copolymer was washed twice with a solvent mixture of 45.4 g of MEK and 194.6 g of hexane. On vacuum drying at 50° C. for 20 hours, 36.6 g of the copolymer (Polymer 1) was obtained in white powder form. The copolymer was analyzed by ¹³C-NMR, finding a copolymer compositional ratio of 5/45/50 mol % in the described order of monomers. The Mw and Mw/Mn of the polymer were determined by GPC.

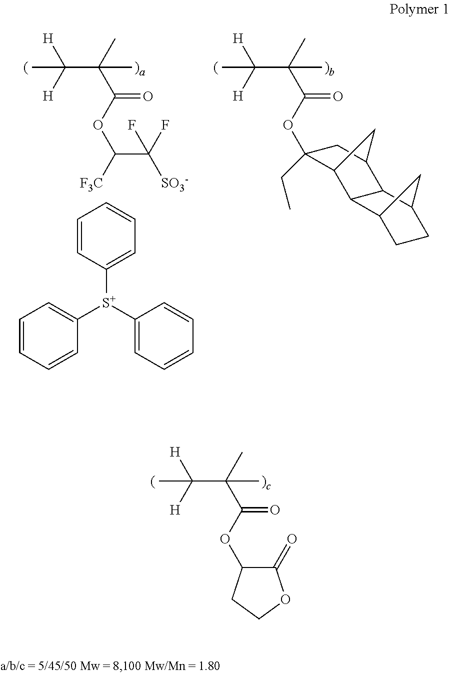

### Examples 1-2 to 1-38 & Comparative Examples 1-1 to 1-10

Synthesis of Polymers 2 to 48

Polymers 2 to 38 (Examples 1-2 to 1-38) were synthesized by the same method as in Example 1-1. Also Polymers 39 to 48 (Comparative Examples 1-1 to 1-10) were similarly synthesized. The composition and compositional ratio of each polymer are shown in Tables 1 and 2 together with its Mw and Mw/Mn. The structure of each recurring unit is shown in Tables 3 to 7. In Table 3, BPU-1 to 7 designate units capable of generating an acid upon exposure to high-energy radiation and corresponding to formula (1a) or (1b), which are derived by copolymerizing Monomers 1 to 7 with other monomers. In Table 5, LU-1 to 4 designate lactone-containing units corresponding to formula (2a) or (2b). In Table 4, ALU-1 to 11 designate acid labile units corresponding to formula (3). In Table 6, PU-1 to 7 designate additional recurring units which may be incorporated in the inventive polymer. In Table 7, HU-1 to 4 are hydroxyl-containing units which must not be incorporated in the inventive polymer.

TABLE 1

| | Unit 1 | | Unit 2 | | Unit 3 | | Unit 4 | | Unit 5 | | | |
|---|---|---|---|---|---|---|---|---|---|---|---|---|
| | | Ratio | | Ratio | | Ratio | | Ratio | | Ratio | Mw | Mw/Mn |
| Polymer 1 | BPU-1 | 5 | ALU-1 | 45 | LU-1 | 50 | | | | | 8,100 | 1.80 |
| Polymer 2 | BPU-1 | 2 | ALU-1 | 48 | LU-1 | 50 | | | | | 7,860 | 1.78 |
| Polymer 3 | BPU-1 | 8 | ALU-1 | 42 | LU-1 | 50 | | | | | 8,250 | 1.69 |
| Polymer 4 | BPU-2 | 5 | ALU-1 | 45 | LU-1 | 50 | | | | | 8,800 | 1.82 |
| Polymer 5 | BPU-3 | 5 | ALU-1 | 45 | LU-1 | 50 | | | | | 8,310 | 1.77 |
| Polymer 6 | BPU-4 | 5 | ALU-1 | 45 | LU-1 | 50 | | | | | 7,940 | 1.84 |
| Polymer 7 | BPU-5 | 5 | ALU-1 | 45 | LU-1 | 50 | | | | | 6,500 | 1.90 |
| Polymer 8 | BPU-6 | 5 | ALU-1 | 45 | LU-1 | 50 | | | | | 6,980 | 1.90 |
| Polymer 9 | BPU-7 | 5 | ALU-1 | 45 | LU-1 | 50 | | | | | 7,540 | 1.75 |
| Polymer 10 | BPU-1 | 5 | ALU-2 | 45 | LU-1 | 50 | | | | | 8,920 | 1.62 |
| Polymer 11 | BPU-1 | 5 | ALU-3 | 45 | LU-1 | 50 | | | | | 6,760 | 1.99 |
| Polymer 12 | BPU-1 | 5 | ALU-4 | 45 | LU-1 | 50 | | | | | 8,030 | 1.80 |
| Polymer 13 | BPU-1 | 5 | ALU-5 | 45 | LU-1 | 50 | | | | | 9,200 | 1.79 |
| Polymer 14 | BPU-1 | 5 | ALU-6 | 45 | LU-1 | 50 | | | | | 8,730 | 1.78 |
| Polymer 15 | BPU-1 | 5 | ALU-7 | 45 | LU-1 | 50 | | | | | 8,220 | 1.88 |
| Polymer 16 | BPU-1 | 5 | ALU-1 | 50 | LU-1 | 45 | | | | | 11,200 | 1.79 |
| Polymer 17 | BPU-1 | 5 | ALU-4 | 60 | LU-1 | 35 | | | | | 8,140 | 1.85 |
| Polymer 18 | BPU-1 | 5 | ALU-1 | 45 | LU-2 | 50 | | | | | 8,060 | 1.76 |
| Polymer 19 | BPU-1 | 2 | ALU-1 | 48 | LU-2 | 50 | | | | | 7,970 | 1.72 |
| Polymer 20 | BPU-1 | 5 | ALU-2 | 45 | LU-2 | 50 | | | | | 8,400 | 1.89 |
| Polymer 21 | BPU-1 | 5 | ALU-3 | 45 | LU-2 | 50 | | | | | 6,910 | 1.92 |
| Polymer 22 | BPU-1 | 5 | ALU-4 | 45 | LU-2 | 50 | | | | | 7,990 | 1.73 |
| Polymer 23 | BPU-1 | 5 | ALU-7 | 45 | LU-2 | 50 | | | | | 8,630 | 1.73 |
| Polymer 24 | BPU-1 | 5 | ALU-1 | 10 | ALU-6 | 35 | LU-1 | 50 | | | 8,030 | 1.78 |
| Polymer 25 | BPU-1 | 5 | ALU-1 | 10 | ALU-6 | 35 | LU-1 | 50 | | | 7,740 | 1.77 |
| Polymer 26 | BPU-1 | 5 | ALU-1 | 10 | ALU-7 | 35 | LU-1 | 50 | | | 8,830 | 1.91 |
| Polymer 27 | BPU-1 | 5 | ALU-4 | 10 | ALU-8 | 35 | LU-1 | 50 | | | 6,840 | 1.83 |
| Polymer 28 | BPU-1 | 5 | ALU-1 | 40 | LU-1 | 40 | LU-2 | 15 | | | 9,200 | 1.78 |
| Polymer 29 | BPU-1 | 3 | BPU-7 | 3 | ALU-1 | 44 | LU-2 | 50 | | | 9,000 | 1.79 |
| Polymer 30 | BPU-1 | 5 | ALU-7 | 50 | LU-1 | 20 | PU-2 | 25 | | | 8,250 | 1.70 |
| Polymer 31 | BPU-1 | 5 | ALU-7 | 55 | LU-1 | 15 | PU-3 | 25 | | | 8,320 | 1.74 |
| Polymer 32 | BPU-1 | 5 | ALU-4 | 45 | LU-1 | 40 | PU-1 | 10 | | | 9,400 | 1.79 |
| Polymer 33 | BPU-1 | 5 | ALU-1 | 5 | ALU-7 | 55 | LU-1 | 15 | PU-3 | 20 | 8,560 | 1.82 |
| Polymer 34 | BPU-1 | 5 | ALU-9 | 10 | ALU-8 | 30 | LU-2 | 45 | PU-4 | 10 | 8,490 | 1.72 |
| Polymer 35 | BPU-1 | 5 | ALU-1 | 40 | LU-1 | 45 | PU-6 | 10 | | | 9,240 | 1.81 |
| Polymer 36 | BPU-1 | 5 | ALU-1 | 45 | LU-1 | 45 | PU-7 | 5 | | | 7,850 | 1.71 |
| Polymer 37 | BPU-2 | 5 | ALU-10 | 35 | LU-3 | 60 | | | | | 8,760 | 1.90 |
| Polymer 38 | BPU-2 | 5 | ALU-11 | 30 | LU-4 | 40 | PU-5 | 25 | | | 9,230 | 1.91 |

TABLE 2

| | Unit 1 | | Unit 2 | | Unit 3 | | Unit 4 | | Unit 5 | | | |
|---|---|---|---|---|---|---|---|---|---|---|---|---|
| | | Ratio | | Ratio | | Ratio | | Ratio | | Ratio | Mw | Mw/Mn |
| Polymer 39 | ALU-1 | 50 | LU-1 | 50 | | | | | | | 7,950 | 1.76 |
| Polymer 40 | ALU-7 | 50 | LU-2 | 50 | | | | | | | 8,200 | 1.82 |
| Polymer 41 | BPU-1 | 5 | ALU-1 | 45 | PU-2 | 50 | | | | | 9,150 | 1.77 |
| Polymer 42 | BPU-1 | 5 | ALU-2 | 45 | PU-1 | 50 | | | | | 8,930 | 1.79 |
| Polymer 43 | BPU-1 | 5 | ALU-6 | 45 | PU-1 | 50 | | | | | 10,020 | 1.89 |
| Polymer 44 | BPU-1 | 5 | ALU-1 | 20 | ALU-6 | 30 | PU-2 | 45 | | | 7,820 | 1.90 |
| Polymer 45 | BPU-1 | 5 | ALU-1 | 10 | ALU-6 | 35 | LU-1 | 40 | HU-1 | 10 | 7,900 | 1.92 |
| Polymer 46 | BPU-1 | 5 | ALU-1 | 10 | ALU-6 | 35 | LU-1 | 40 | HU-2 | 10 | 8,240 | 1.88 |
| Polymer 47 | BPU-1 | 5 | ALU-1 | 10 | ALU-6 | 35 | LU-1 | 40 | HU-3 | 10 | 8,300 | 1.90 |
| Polymer 48 | BPU-1 | 5 | ALU-1 | 10 | ALU-6 | 35 | LU-1 | 40 | HU-4 | 10 | 8,770 | 1.86 |

TABLE 3

| | |
|---|---|
| 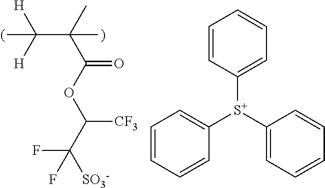 | BPU-1 |
| 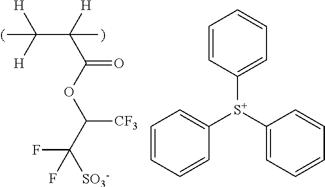 | BPU-2 |
| 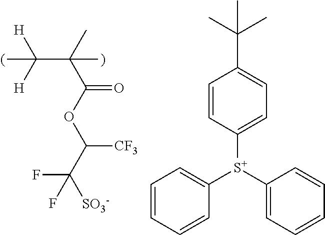 | BPU-3 |
| 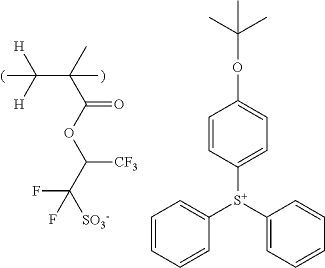 | BPU-4 |
| 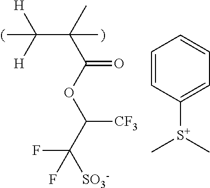 | BPU-5 |
| 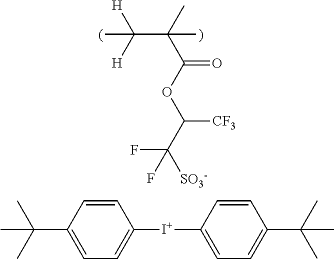 | BPU-6 |
| 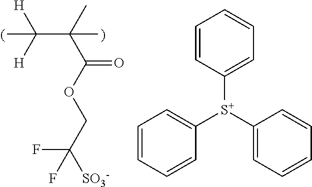 | BPU-7 |

TABLE 4

| | |
|---|---|
| 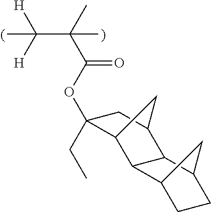 | ALU-1 |
| 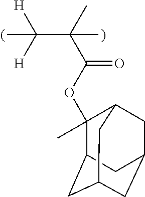 | ALU-2 |
| 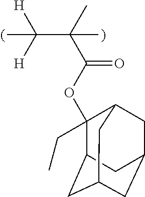 | ALU-3 |
| 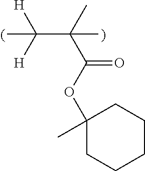 | ALU-4 |
| 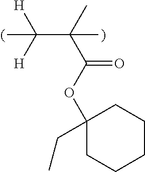 | ALU-5 |
| 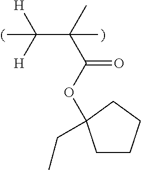 | ALU-6 |
| 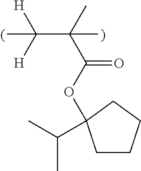 | ALU-7 |
| 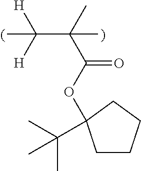 | ALU-8 |
| 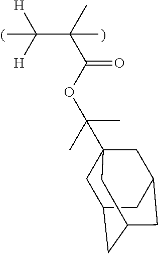 | ALU-9 |
| 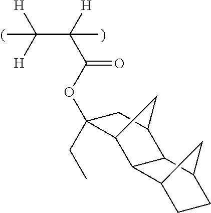 | ALU-10 |
| 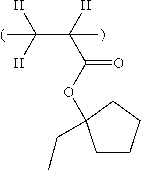 | ALU-11 |

TABLE 5

| | |
|---|---|
| 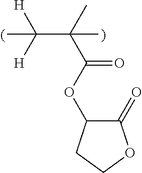 | LU-1 |
| 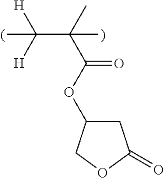 | LU-2 |
| 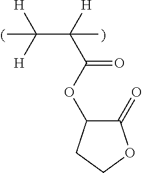 | LU-3 |
| 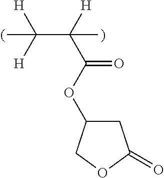 | LU-4 |

TABLE 6

| | |
|---|---|
| 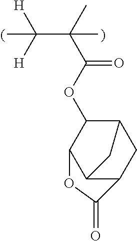 | PU-1 |
| 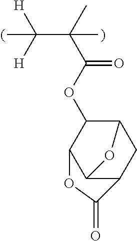 | PU-2 |
| 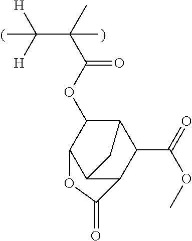 | PU-3 |
| 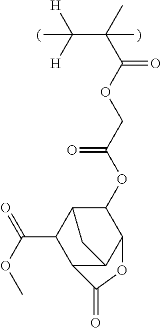 | PU-4 |
| 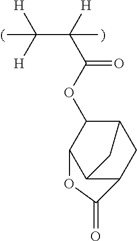 | PU-5 |
| 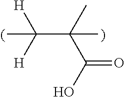 | PU-6 |
| 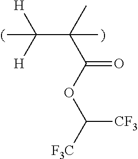 | PU-7 |

TABLE 7

| | |
|---|---|
| 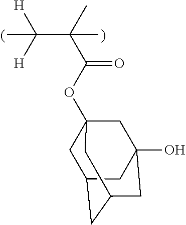 | HU-1 |
| 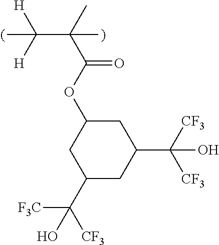 | HU-2 |
| 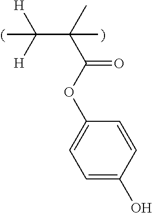 | HU-3 |
| 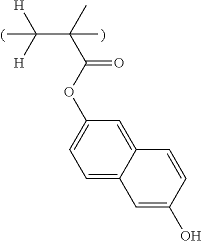 | HU-4 |

### Examples 2-1 to 2-41 & Comparative Examples 2-1 to 2-10

### [Preparation of Resist Material]

Resist compositions PR-1 to 41 (Examples 2-1 to 2-41) as formulated in Tables 8 and 9 were prepared by dissolving the polymer, photoacid generator and quencher in a solvent, and filtering through a Teflon® filter having a pore size of 0.2 μm. Comparative Resist compositions PR-42 to 51 (Comparative Examples 2-1 to 2-10) as formulated in Table 10 were similarly prepared. The PAGs in Tables 8 to 10 have the structures shown in Table 11.

TABLE 8

| | Polymer | PAG | Quencher | Solvent |
|---|---|---|---|---|
| Resist | (pbw) | (pbw) | (pbw) | (pbw) |
| PR-1 | Polymer-1 | | PhBIz | PGMEA(2,700) |
| | (100) | | (1.6) | GBL(300) |
| PR-2 | Polymer-2 | PAG-1 | PhBIz | PGMEA(2,700) |
| | (100) | (5.1) | (1.6) | GBL(300) |
| PR-3 | Polymer-3 | | PhBIz | PGMEA(2,700) |
| | (100) | | (1.6) | GBL(300) |
| PR-4 | Polymer-4 | | PhBIz | PGMEA(2,700) |
| | (100) | | (1.6) | GBL(300) |
| PR-5 | Polymer-5 | | PhBIz | PGMEA(2,700) |
| | (100) | | (1.6) | GBL(300) |
| PR-6 | Polymer-6 | | PhBIz | PGMEA(2,700) |
| | (100) | | (1.6) | GBL(300) |
| PR-7 | Polymer-7 | | PhBIz | PGMEA(2,700) |
| | (100) | | (1.6) | GBL(300) |
| PR-8 | Polymer-8 | | PhBIz | PGMEA(2,700) |
| | (100) | | (1.6) | GBL(300) |
| PR-9 | Polymer-9 | | PhBIz | PGMEA(2,700) |
| | (100) | | (1.6) | GBL(300) |
| PR-10 | Polymer-10 | | PhBIz | PGMEA(2,700) |
| | (100) | | (1.6) | GBL(300) |
| PR-11 | Polymer-11 | | PhBIz | PGMEA(2,700) |
| | (100) | | (1.6) | GBL(300) |
| PR-12 | Polymer-12 | | PhBIz | PGMEA(2,700) |
| | (100) | | (1.6) | GBL(300) |
| PR-13 | Polymer-13 | | PhBIz | PGMEA(2,700) |
| | (100) | | (1.6) | GBL(300) |
| PR-14 | Polymer-14 | | PhBIz | PGMEA(2,700) |
| | (100) | | (1.6) | GBL(300) |
| PR-15 | Polymer-15 | | PhBIz | PGMEA(2,700) |
| | (100) | | (1.6) | GBL(300) |
| PR-16 | Polymer-16 | | PhBIz | PGMEA(2,700) |
| | (100) | | (1.6) | GBL(300) |
| PR-17 | Polymer-17 | | PhBIz | PGMEA(2,700) |
| | (100) | | (1.6) | GBL(300) |
| PR-18 | Polymer-18 | | PhBIz | PGMEA(2,700) |
| | (100) | | (1.6) | GBL(300) |
| PR-19 | Polymer-19 | PAG-1 | PhBIz | PGMEA(2,700) |
| | (100) | (5.1) | (1.6) | GBL(300) |
| PR-20 | Polymer-20 | | PhBIz | PGMEA(2,700) |
| | (100) | | (1.6) | GBL(300) |
| PR-21 | Polymer-21 | | PhBIz | PGMEA(2,700) |
| | (100) | | (1.6) | GBL(300) |
| PR-22 | Polymer-22 | | PhBIz | PGMEA(2,700) |
| | (100) | | (1.6) | GBL(300) |
| PR-23 | Polymer-23 | | PhBIz | PGMEA(2,700) |
| | (100) | | (1.6) | GBL(300) |
| PR-24 | Polymer-24 | | PhBIz | PGMEA(2,700) |
| | (100) | | (1.6) | GBL(300) |
| PR-25 | Polymer-25 | | PhBIz | PGMEA(2,700) |
| | (100) | | (1.6) | GBL(300) |

TABLE 9

| | Polymer | PAG | Quencher | Solvent |
|---|---|---|---|---|
| Resist | (pbw) | (pbw) | (pbw) | (pbw) |
| PR-26 | Polymer-26 | | PhBIz | PGMEA(2,700) |
| | (100) | | (1.6) | GBL(300) |
| PR-27 | Polymer-27 | | PhBIz | PGMEA(2,700) |
| | (100) | | (1.6) | GBL(300) |
| PR-28 | Polymer-28 | | PhBIz | PGMEA(2,700) |
| | (100) | | (1.6) | GBL(300) |
| PR-29 | Polymer-29 | | PhBIz | PGMEA(2,700) |
| | (100) | | (1.6) | GBL(300) |
| PR-30 | Polymer-30 | | PhBIz | PGMEA(2,700) |
| | (100) | | (1.6) | GBL(300) |
| PR-31 | Polymer-31 | | PhBIz | PGMEA(2,700) |
| | (100) | | (1.6) | GBL(300) |
| PR-32 | Polymer-32 | | PhBIz | PGMEA(2,700) |
| | (100) | | (1.6) | GBL(300) |
| PR-33 | Polymer-33 | | PhBIz | PGMEA(2,700) |
| | (100) | | (1.6) | GBL(300) |
| PR-34 | Polymer-34 | | PhBIz | PGMEA(2,700) |
| | (100) | | (1.6) | GBL(300) |
| PR-35 | Polymer-35 | | PhBIz | PGMEA(2,700) |
| | (100) | | (1.6) | GBL(300) |
| PR-36 | Polymer-36 | | PhBIz | PGMEA(2,700) |
| | (100) | | (1.6) | GBL(300) |
| PR-37 | Polymer-37 | | PhBIz | PGMEA(2,700) |
| | (100) | | (1.6) | GBL(300) |
| PR-38 | Polymer-38 | | PhBIz | PGMEA(2,700) |
| | (100) | | (1.6) | GBL(300) |
| PR-39 | Polymer-2 | PAG-2 | PhBIz | PGMEA(2,700) |
| | (100) | (6.9) | (1.6) | GBL(300) |
| PR-40 | Polymer-2 | PAG-3 | | PGMEA(2,700) |
| | (100) | (3.8) | | GBL(300) |
| PR-41 | Polymer-19 | PAG-4 | | PGMEA(2,700) |
| | (100) | (4.2) | | GBL(300) |

TABLE 10

| | Polymer | PAG | Quencher | Solvent |
|---|---|---|---|---|
| Resist | (pbw) | (pbw) | (pbw) | (pbw) |
| PR-42 | Polymer-39 | PAG-1 | PhBIz | PGMEA(2,700) |
| | (100) | (12.7) | (1.6) | GBL(300) |
| PR-43 | Polymer-40 | PAG-1 | PhBIz | PGMEA(2,700) |
| | (100) | (12.7) | (1.6) | GBL(300) |
| PR-44 | Polymer-41 | | PhBIz | PGMEA(2,700) |
| | (100) | | (1.6) | GBL(300) |
| PR-45 | Polymer-42 | | PhBIz | PGMEA(2,700) |
| | (100) | | (1.6) | GBL(300) |
| PR-46 | Polymer-43 | | PhBIz | PGMEA(2,700) |
| | (100) | | (1.6) | GBL(300) |
| PR-47 | Polymer-44 | | PhBIz | PGMEA(2,700) |
| | (100) | | (1.6) | GBL(300) |
| PR-48 | Polymer-45 | | PhBIz | PGMEA(2,700) |
| | (100) | | (1.6) | GBL(300) |
| PR-49 | Polymer-46 | | PhBIz | PGMEA(2,700) |
| | (100) | | (1.6) | GBL(300) |
| PR-50 | Polymer-47 | | PhBIz | PGMEA(2,700) |
| | (100) | | (1.6) | GBL(300) |
| PR-51 | Polymer-48 | | PhBIz | PGMEA(2,700) |
| | (100) | | (1.6) | GBL(300) |

TABLE 11

| | |
|---|---|
| 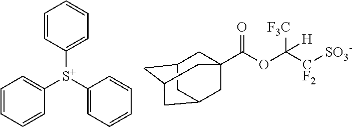 | PAG-1 |
| 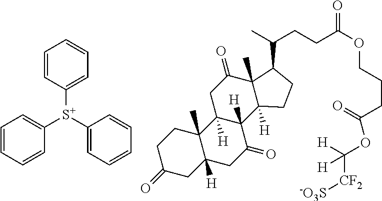 | PAG-2 |
| 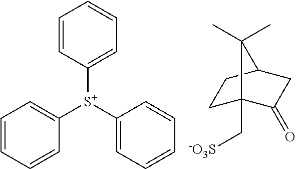 | PAG-3 |
| 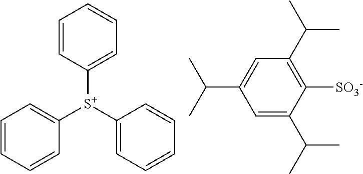 | PAG-4 |

It is noted that the quencher and the solvents in Tables 8 to 10 are identified below.

PhBIz: 2-phenylbenzimidazole
PGMEA: propylene glycol monomethyl ether acetate
GBL: γ-butyrolactone

All the resist compositions in Tables 8 to 10 contained 5.0 parts by weight of an alkali-soluble surfactant SF-1 and 0.1 part by weight of a surfactant A, which are identified below.

### Alkali-soluble surfactant SF-1: poly(3,3,3-trifluoro-2-hydroxy-1,1-dimethyl-2-trifluoromethylpropyl methacrylate/1,1,1-trifluoro-2-hydroxy-6-methyl-2-trifluoro-methylhept-4-yl methacrylate) (described in JP-A 2008-122932)

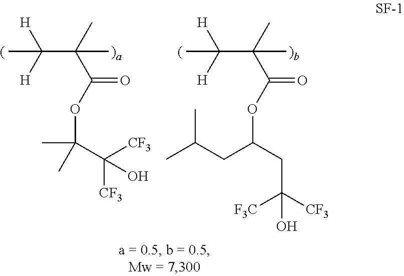

### Surfactant A: 3-methyl-3-(2,2,2-trifluoroethoxymethyl)oxetane/tetrahydrofuran/2,2-dimethyl-1,3-propane diol (Omnova Solutions, Inc.)

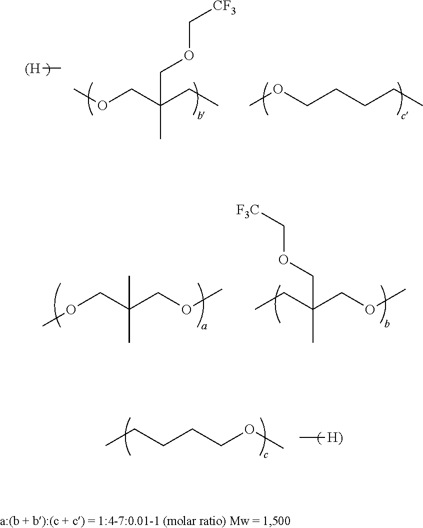

### Examples 3-1 to 3-41 & Comparative Examples 3-1 to 3-10

An antireflective coating solution (ARC-29A by Nissan Chemical Industries Co., Ltd.) was coated onto a silicon substrate and baked at 200° C. for 60 seconds to form an ARC film of 100 nm thick. The resist solution was spin coated onto the ARC film and baked on a hot plate at 100° C. for 60 seconds to form a resist film of 90 nm thick. The resist film was exposed according to the ArF immersion lithography using an ArF excimer laser scanner NSR—S610C (Nikon Corp., NA 1.30, dipole illumination, 6% halftone phase shift mask). The resist film was baked (PEB) at an arbitrary temperature for 60 seconds and developed with a 2.38 wt % aqueous solution of tetramethylammonium hydroxide for 60 seconds.

The resist was evaluated by observing a 40-nm 1:1 line-and-space pattern under an electron microscope. The optimum dose (Eop) was a dose (mJ/cm²) which provided a line width of 40 nm. The profile of a pattern at the optimum dose was compared and judged passed or rejected according to the following criterion.
Passed: pattern of rectangular profile with perpendicular sidewall
Rejected: pattern of tapered profile with sharply graded sidewall or of top-rounded profile due to top loss

The collapse limit was a minimum width (nm) of lines which could be resolved without collapse when the line width was reduced by increasing the exposure dose. A smaller value indicates better collapse resistance.

The PEB temperature and evaluation results of the resist compositions in Tables 8 and 9 are tabulated in Table 12. The PEB temperature and evaluation results of the comparative resist compositions in Table 10 are tabulated in Table 13.

TABLE 12

| | | PEB | Eop | | Collapse limit |
|---|---|---|---|---|---|
| | Resist | (° C.) | (mJ/cm²) | Profile | (nm) |
| Example 3-1 | PR-1 | 100 | 31 | Passed | 27 |
| Example 3-2 | PR-2 | 100 | 32 | Passed | 30 |
| Example 3-3 | PR-3 | 100 | 32 | Passed | 29 |
| Example 3-4 | PR-4 | 100 | 30 | Passed | 28 |
| Example 3-5 | PR-5 | 100 | 35 | Passed | 27 |
| Example 3-6 | PR-6 | 100 | 41 | Passed | 29 |
| Example 3-7 | PR-7 | 100 | 43 | Passed | 29 |
| Example 3-8 | PR-8 | 100 | 49 | Passed | 30 |
| Example 3-9 | PR-9 | 100 | 33 | Passed | 26 |
| Example 3-10 | PR-10 | 110 | 36 | Passed | 24 |
| Example 3-11 | PR-11 | 105 | 34 | Passed | 26 |
| Example 3-12 | PR-12 | 105 | 30 | Passed | 30 |
| Example 3-13 | PR-13 | 100 | 30 | Passed | 28 |
| Example 3-14 | PR-14 | 100 | 27 | Passed | 28 |
| Example 3-15 | PR-15 | 95 | 28 | Passed | 27 |
| Example 3-16 | PR-16 | 95 | 35 | Passed | 26 |
| Example 3-17 | PR-17 | 105 | 30 | Passed | 28 |
| Example 3-18 | PR-18 | 100 | 32 | Passed | 26 |
| Example 3-19 | PR-19 | 100 | 29 | Passed | 26 |
| Example 3-20 | PR-20 | 110 | 37 | Passed | 27 |
| Example 3-21 | PR-21 | 105 | 34 | Passed | 30 |
| Example 3-22 | PR-22 | 105 | 34 | Passed | 29 |
| Example 3-23 | PR-23 | 95 | 26 | Passed | 28 |
| Example 3-24 | PR-24 | 100 | 31 | Passed | 28 |
| Example 3-25 | PR-25 | 105 | 30 | Passed | 29 |
| Example 3-26 | PR-26 | 95 | 29 | Passed | 30 |
| Example 3-27 | PR-27 | 90 | 33 | Passed | 29 |
| Example 3-28 | PR-28 | 100 | 32 | Passed | 28 |
| Example 3-29 | PR-29 | 100 | 38 | Passed | 30 |
| Example 3-30 | PR-30 | 105 | 30 | Passed | 27 |
| Example 3-31 | PR-31 | 105 | 34 | Passed | 30 |
| Example 3-32 | PR-32 | 110 | 32 | Passed | 27 |
| Example 3-33 | PR-33 | 105 | 31 | Passed | 32 |
| Example 3-34 | PR-34 | 100 | 28 | Passed | 29 |
| Example 3-35 | PR-35 | 90 | 33 | Passed | 31 |
| Example 3-36 | PR-36 | 90 | 35 | Passed | 31 |
| Example 3-37 | PR-37 | 80 | 38 | Passed | 32 |
| Example 3-38 | PR-38 | 90 | 37 | Passed | 30 |
| Example 3-39 | PR-39 | 100 | 30 | Passed | 31 |
| Example 3-40 | PR-40 | 100 | 24 | Passed | 31 |
| Example 3-41 | PR-41 | 100 | 25 | Passed | 32 |

TABLE 13

| | | PEB | Eop | | Collapse limit |
|---|---|---|---|---|---|
| | Resist | (° C.) | (mJ/cm²) | Profile | (nm) |
| Comparative | PR-42 | 100 | 27 | Rejected | 38 |
| Example 3-1 | | | | | |
| Comparative | PR-43 | 100 | 28 | Rejected | 39 |
| Example 3-2 | | | | | |
| Comparative | PR-44 | 105 | 30 | Passed | 39 |
| Example 3-3 | | | | | |
| Comparative | PR-45 | 110 | 31 | Passed | 39 |
| Example 3-4 | | | | | |
| Comparative | PR-46 | 105 | 30 | Passed | 38 |
| Example 3-5 | | | | | |
| Comparative | PR-47 | 105 | 29 | Passed | 39 |
| Example 3-6 | | | | | |
| Comparative | PR-48 | 100 | 35 | Passed | 39 |
| Example 3-7 | | | | | |
| Comparative | PR-49 | 100 | 34 | Rejected | 35 |
| Example 3-8 | | | | | |
| Comparative | PR-50 | 100 | 35 | Rejected | 33 |
| Example 3-9 | | | | | |
| Comparative | PR-51 | 100 | 32 | Rejected | 33 |
| Example 3-10 | | | | | |

As seen from the data in Tables 12 and 13, resist compositions comprising polymers within the scope of the invention are effective for meeting both satisfactory pattern profile and collapse resistance.

While the invention has been illustrated and described in typical embodiments, it is not intended to be limited to the details shown. Any modified embodiments having substantially the same features and achieving substantially the same results as the technical idea disclosed herein are within the spirit and scope of the invention. For example, although the resist composition is described mainly as being processed by the immersion lithography, the resist composition is equally effective when processed by conventional lithography other than the immersion lithography.

Japanese Patent Application No. 2010-262372 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A polymer comprising
recurring units of a structure adapted to generate an acid in response to high-energy radiation selected from UV, deep UV, electron beam, x-ray, excimer laser, γ-ray and synchrotron radiation, having the general formula (1a) and/or (1b),
recurring units of a lactone ring-containing structure having the general formula (2a) and/or (2b), and
acid labile units having the general formula (3),
all the recurring units being free of hydroxyl, 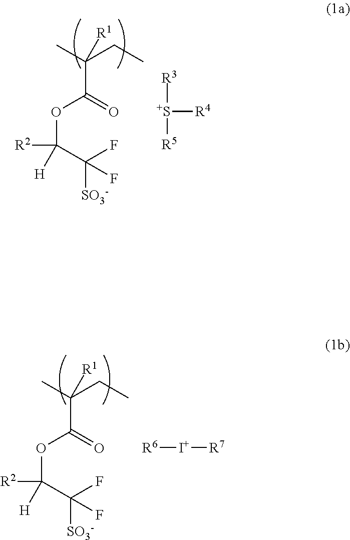
wherein R¹ is hydrogen or methyl, R² is hydrogen or trifluoromethyl, R², R⁴, and R⁵ are each independently a substituted or unsubstituted, straight, branched or cyclic C₁-C₁₀ alkyl, alkenyl or oxoalkyl group, or substituted or unsubstituted C₆-C₁₈ aryl, aralkyl or aryloxoalkyl group, any two of R³, R⁴, and R⁵ may bond together to form a ring with the sulfur atom, R⁶ and R⁷ are each independently a substituted or unsubstituted C₆-C₁₈ aryl group, 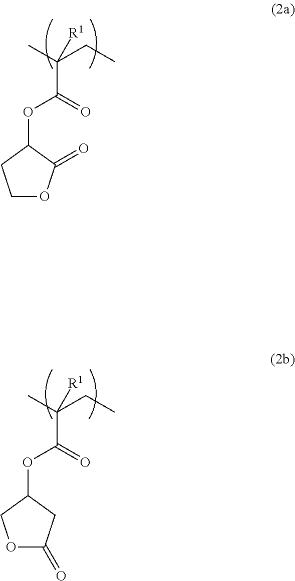
wherein R¹ is hydrogen or methyl, 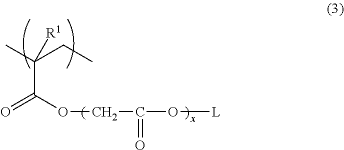
wherein R¹ is hydrogen or methyl, x is 0 or 1, and L is an acid labile group.

2. A positive resist composition comprising the polymer of claim 1 as a base resin.

3. A pattern forming process comprising the steps of coating the positive resist composition of claim 2 onto a substrate and heat treating to form a resist film, exposing the resist film to high-energy radiation, and developing with a developer.

4. The process of claim 3 wherein the high-energy radiation has a wavelength in the range of 180 to 250 nm.

5. The process of claim 3 wherein the exposing step is to expose the resist film to high-energy radiation via a liquid according to the immersion lithography.

6. The process of claim 5, further comprising the step of forming a protective film on the resist film,
the exposing step of immersion lithography including interposing a liquid between the protective film and a projection lens.

7. The process of claim 6 wherein the high-energy radiation has a wavelength in the range of 180 to 250 nm.

8. The process of claim 7 wherein the liquid is water.
